(19) United States
(12) Patent Application Publication
(10) Pub. No.: US 2026/0121290 A1
(43) Pub. Date: Apr. 30, 2026

(54) SWITCHED TRANSFORMER ARRAYS AND SWITCHED INDUCTOR ARRAYS CAPABLE OF USE IN BEAMFORMER INTEGRATED CIRCUITS

(71) Applicant: QUALCOMM INCORPORATED, SAN DIEGO, CA (US)

(72) Inventors: Lisette ZHANG, Vista, CA (US); Chinmaya MISHRA, San Diego, CA (US)

(21) Appl. No.: 18/928,885

(22) Filed: Oct. 28, 2024

(51) Int. Cl. H01Q 3/24; H01F 27/28; H03F 3/24

(52) U.S. Cl. CPC H01Q 3/24; H01F 27/2804; H03F 3/245; H01F 2027/2809; H03F 2200/451

(57) ABSTRACT

A switched transformer array is provided that can be used in a beamformer integrated circuit (BFIC) or other circuits and can be configured to transmit and receive all of the frequencies of the entire 5G or 6G frequency range, or a portion thereof such as FR2 and/or FR3. For example, if designed for use in a 5G or 6G system that utilizes the FR2 range, a single switched transformer array of the present disclosure can cover the entire FR2 range (24 GHz to 71 GHz) in a BFIC that is approximately one-third of the size of current BFICs that use split architectures to cover the FR2 range.

Consequently, incorporation of the switched transformer array in a BFIC allows the BFIC to be reduced in size and complexity and/or allows it to achieve ultra-broadband operations and agile and fast frequency hopping for better performance and improved security in 5G/6G networks. The BFIC may have inherent emission filtering and improved in-band image rejection.

### FIELD

The present disclosure relates generally to electronics, and more specifically, to switched transformer arrays and switched inductor arrays suitable for use in beamformer integrated circuits (BFICs) and/or other circuits.

### BACKGROUND

Wireless communication devices and technologies are becoming ever more prevalent as are communication systems that operate at millimeter-wave (mmW) and at near-mmW frequencies. Conventional 5G mmW beamformer integrated circuits (BFICs) employ a split (or split-and-merge) architecture in which the Frequency Range 2 (FR2) low band, FR2a (24.25 GHz˜29.5 GHz), the FR2 mid band, FR2b (37 GHz˜43.5 GHz) and the FR2 high band, FR2c (47.2 GHz˜48.2 GHz) are transmitted and received using dedicated circuits for each frequency range. Because dedicated circuits are used for each frequency range, this architecture increases the chip size and complexity, which, in turn, makes the BFICs generally unsuitable for use in limited volume devices, increases BFIC cost and results in other disadvantages.

Also, the need for high equivalent isotropic radiated power (EIRP) in antenna systems that utilize patch antennas is typically met by flip-chip mounting large beamformer arrays on small patch antenna arrays, the size of which are inversely proportional to frequencies. The 5^{th} generation new-radio (5G NR) mobile communication systems utilize mmW frequencies, enabling wider bandwidths, higher-order modulations, and spatial-division multiple access in combination with multiple-input multiple-output (MIMO) capability. Therefore, the large size of the current BFICs may make them unsuitable for use in such mobile communications systems.

Additionally, broadband amplifiers, which are essential building blocks of high data rate wireless, radar, and instrumentation systems of the type that are currently used in, or proposed for use in, 5G and 6G mmW systems generally have low power efficiency and low rejection that generally do not meet Federal Communications Commission (FCC) requirements for the military frequency band (31 GHz to 37 GHz) unless they employ an additional bandpass filter.

A need exists for a BFIC having reduced chip size and improved power efficiency and rejection. Further, it may be beneficial to support broadband frequency hopping spread spectrum (FHSS) applications with high agility and very fast switching times without Q and insertion loss degradation.

### SUMMARY

Various implementations of systems, methods and devices within the scope of the appended claims each have several aspects, no single one of which is solely responsible for the desirable attributes described herein. Without limiting the scope of the appended claims, some prominent features are described herein.

An exemplary embodiment of the system comprises a BFIC comprising a switched transformer array. In accordance with this embodiment, the switched transformer array comprises a transformer primary side, a transformer secondary side, at least a first inductor strand, at least a second inductor strand, a first switch, and a second switch. The transformer primary side comprises at least a first transformer turn formed in a first metal layer of the BFIC and having first and second ends. The transformer secondary side comprises at least a first transformer turn formed in a second metal layer of the BFIC and having first and second ends. The first inductor strand is formed in the first metal layer a first distance from the first transformer turn of the transformer primary side. The first inductor strand has first and second ends. The second inductor strand is formed in one of the first metal layer and the second metal layer a second distance from the first inductor strand. The second inductor strand having first and second ends. The first switch is configured to selectively interconnect the first and second ends of the first inductor strand. The second switch is configured to selectively interconnect the first and second ends of the second inductor strand.

Another exemplary embodiment of the system comprises a BFIC comprising a switched inductor array comprising N inductor strands and at least N−1 switches. The N inductor strands are formed in a first metal layer of the BFIC preselected distances from one another, where N is a positive integer that is greater than or equal to 3. Each of the inductor strands has first and second ends and is substantially circularly shaped and concentrically oriented in the first metal layer. The at least N−1 switches interconnect the first and second ends of N−1 of the inductor strands, respectively. The N−1 switches are configured to be activated and to be deactivated. Activation of one or more of the switches changes electromagnetic inductive characteristics of the switched inductor array, thereby changing an operating frequency of the first inductor array.

Another exemplary embodiment of the system comprises a BFIC comprising a switched transformer array comprising a first transformer, a second transformer and first, second third and fourth inductor strands. The first transformer comprises a first transformer primary side and a first transformer secondary side. The first transformer primary side comprises at least a first transformer turn formed in a first metal layer of the BFIC. The first transformer secondary side comprises at least a second transformer turn formed in a second metal layer of the BFIC. The second transformer comprises a second transformer primary side and a second transformer secondary side. The second transformer primary side comprises at least a third transformer turn formed in the first metal layer of the BFIC. The second transformer secondary side comprises at least a fourth transformer turn formed in the second metal layer of the BFIC. The first inductor strand is formed in the first metal layer a first distance from the first transformer turn.

The second inductor strand is formed in the second metal layer a second distance from the second transformer turn. The third inductor strand is formed in the first metal layer a third distance from the third transformer turn. The fourth inductor strand is formed in the second metal layer a fourth distance from the fourth transformer turn.

Details of one or more implementations of the subject matter described in this specification are set forth in the accompanying drawings and the description below. Other features, aspects, and advantages will become apparent from the description, the drawings, and the claims. Note that the relative dimensions of the following figures may not be drawn to scale.

These and other features and advantages will become apparent from the following description, drawings and claims.

### BRIEF DESCRIPTION OF THE DRAWINGS

In the figures, like reference numerals refer to like parts throughout the various views unless otherwise indicated. For reference numerals with letter character designations such as “102a” or “102b”, the letter character designations may differentiate two like parts or elements present in the same figure. Letter character designations for reference numerals may be omitted when it is intended that a reference numeral encompass all parts having the same reference numeral in all figures.

FIG. 1 is a diagram showing a wireless device communicating with a wireless communication system in accordance with an exemplary embodiment.

FIG. 2A is a block diagram showing a wireless device in which exemplary techniques of the present disclosure may be implemented.

FIG. 2B shows a block diagram showing a wireless device in which exemplary techniques of the present disclosure may be implemented.

FIG. 2C is a block diagram showing a wireless device in which exemplary techniques of the present disclosure may be implemented.

FIG. 3 shows a conceptual diagram of a switched transformer array in accordance with an exemplary embodiment that may be employed in, for example, one or more of the devices of the systems shown in FIG. 1-2C.

FIG. 4A shows a top perspective view of a portion of a switched transformer array formed in multiple metal layers of a BFIC in accordance with an exemplary embodiment.

FIG. 4B shows a bottom perspective view of the portion of a switched transformer array shown in FIG. 4A flipped over, i.e., rotated by 180° about the X-axis.

FIG. 5 shows a side cross-sectional view of a metal stack comprising the switched transformer array shown in FIGS. 4A and 4B in accordance with an exemplary embodiment.

FIG. 6 shows a block diagram of an amplifier in accordance with an exemplary embodiment that incorporates switched transformer arrays of the present disclosure.

FIG. 7 shows a block diagram of an amplifier in accordance with an exemplary embodiment that incorporates a switched transformer array of the present disclosure.

FIG. 8 shows a block diagram of a voltage-controlled oscillator (VCO) in accordance with an exemplary embodiment that incorporates a switched transformer array of the present disclosure.

FIG. 9 shows a group of plots of the frequency responses of a power amplifier that can have the configuration shown in FIG. 6 or 7 that incorporate the switched transformer arrays of the present disclosure.

FIG. 10 shows groups of plots of gain vs. frequency and noise factor (NF) vs. frequency for a low noise amplifier having the configurations shown in FIG. 6 or 7 that incorporate the switched transformer arrays of the present disclosure.

FIG. 11 shows a portion of a switched inductor array in accordance with an exemplary embodiment.

FIG. 12 is a flow diagram representing a method in accordance with an exemplary embodiment.

FIG. 13 is a flow diagram representing a method in accordance with another exemplary embodiment.

FIG. 14 shows a block diagram of a wireless communications system in accordance with an exemplary embodiment that incorporates one or more instances of the switched transformer array of the present disclosure.

FIG. 15 shows a group of plots of the frequency responses of a power amplifier that can have the configuration shown in FIG. 6 or 7, which incorporates one or more switched capacitor arrays and one or more switched transformer arrays.

### DETAILED DESCRIPTION

The terminology used herein is for purposes of describing particular embodiments only and is not intended to be limiting.

The word “exemplary” is used herein to mean “serving as an example, instance, or illustration.” Any aspect described herein as “exemplary” is not necessarily to be construed as preferred or advantageous over other aspects.

As used in the specification and appended claims, the terms “a,” “an,” and “the” include both singular and plural referents, unless the context clearly dictates otherwise. Thus, for example, “a device” includes one device and plural devices.

Relative terms may be used to describe the various elements'relationships to one another, as illustrated in the accompanying drawings. These relative terms are intended to encompass different orientations of the device and/or elements in addition to the orientation depicted in the drawings.

It will be understood that when an element is referred to as being “connected to” another element, it can be directly connected to the other element or intervening elements may be present.

In accordance with an exemplary embodiment, a switched transformer array is provided that can be used in a BFIC and can be configured to transmit and receive all of the frequencies of the entire 5G or 6G frequency range, or a portion thereof such as FR2 and/or FR3. For example, if designed for use in a 5G or 6G system that utilizes the FR2 range, a single switched transformer array of the present disclosure can cover the entire FR2 range (24 GHz to 71GHz) in a BFIC that is approximately one-third the size of current BFICs that use the aforementioned split architecture to cover the FR2 range. Consequently, incorporation of the switchable transformer array in a BFIC allows the BFIC to be reduced in size and complexity while also allowing it to achieve ultra-broadband operations and very agile and optionally fast FHSS communications for better performance and improved security in 5G and 6G networks. In addition, the BFIC of the present disclosure may inherently filter emissions and/or achieve improved in-band image rejection compared to current BFICs.

Other key benefits of using the switched transformer array in a BFIC include, for example: ability to achieve broadband frequency response with reconfigurability of broad bandwidths in, for example, 5G/6G networks, automotive radar systems, imaging systems, and satellite systems; high out-band and side-band rejection performance; low latency due to the speed with which the switched inductor or transformer arrays respond when switched; ultra reliable communication links in terms of communication security and resistance to narrow band jammers achieved through switching the switched arrays to perform broadband spread spectrum frequency hopping; further reduction in size of the BFIC by employing the switched transformer arrays in multiple circuit blocks of the BFIC, such as in low noise amplifiers (LNAs), power amplifiers (PAs), voltage-controlled oscillators (VCOs), variable gain amplifiers (VGAs), phase shifters, etc.; ability to deploy on both silicon transceiver system-on-a-chip (SoCs) and on Multi-chip-Module RF front-ends (RFEEs) for high sideband rejection multi-subcarrier broadband communications.

In accordance with an exemplary embodiment, a switched transformer array is provided that comprises at least a first transformer and an array of N switched inductors, where N is a positive integer that is greater than or equal to one. The first transformer has at least one primary-side turn formed in first and third metal layers of the BFIC and at least one secondary-side turn formed in second and fourth metal layers of the BFIC, where the second metal layer is disposed in between the first and third metal layers and the third metal layer is disposed in between the second and fourth metal layers. The N switched inductors are located in preselected positions relative to the position of the first transformer. For example, the N switched inductors may extend along side the turns of the transformer, spaced apart from the turns and from one another by a preselected spacing. Each switched inductor includes a switch that can be placed in an opened state or a closed state to turn the switched inductor off and on, respectively.

If the switched transformer array is incorporated into, for example, a broadband amplifier, the primary side of the first transformer can be connected to the drain of a cascode differential pair of the amplifier and the secondary side can be connected to the gate of a cascode differential pair of the next stage of the amplifier. In such configurations, turning the switched inductor(s) off or on changes the inductance of the switched transformer array, which changes the operating frequency and other characteristics of the amplifier.

In accordance with another exemplary embodiment, a switched inductor array is provided that comprises an N−strand inductor comprising N inductor strands that are concentrically formed in at least a first metal layer of a BFIC, where N is a positive integer that is greater than or equal to two. N−1 of the inductor strands can be switched inductor strands that include respective switches that can be placed in an opened state or a closed state to turn the respective inductor strands off and on, respectively. At least one of the inductor strands is a non-switched inductor strand.

If the switched inductor array is incorporated into, for example, an amplifier of a BFIC, the ends of the non-switched inductor strand(s) can be connected to the drain of a cascode differential pair of the amplifier. Opposite ends of each switched inductor strand can be interconnected via a switch that is controlled via one or more control bits to turn the switch off and on, thereby turning the switched inductor strand off and on, respectively. For example, each switch can be a metal oxide field effect transistor (MOSFET) and opposite ends of the switched inductor strand can be connected to the source and drain of the MOSFET, in which case the gate of the MOSFET receives the control bit(s), typically through a high-ohm resistor (e.g., 20 kΩ). In such a configuration, turning the switched inductor(s) off or on changes the inductance of the switched inductor array, which changes the operating frequency and other characteristics of the amplifier.

In accordance with another exemplary embodiment, a switched inductor array is provided that comprises an N−strand inductor comprising N inductor strands that are concentrically formed in at least a first metal layer of a BFIC, where N is an odd-number integer that is greater than or equal to three. N−1 of the inductor strands can be switched inductor strands that include N−1 switches, respectively, that can be placed in an opened state or a closed state to turn the respective switched inductor strand off and on, respectively. Opposite ends of each switched inductor strand can be interconnected via a switch that is controlled via one or more control bits to turn the switch off and on, thereby turning the switched inductor strand off and on, respectively. For example, each switch can be a MOSFET and opposite ends of the switched inductor strand can be connected to the source and drain of the MOSFET, in which case the gate of the MOSFET receives the control bit(s), typically through a high-ohm resistor (e.g., 20 kΩ).

At least the #(N+1)/2 inductor strand can be a non-switched inductor strand. If the switched inductor array is incorporated into, for example, an amplifier of a BFIC, the ends of the non-switched inductor strand(s) can be connected to the drain of a cascode differential pair of the amplifier. In such a configuration, turning the switched inductor(s) off or on changes the inductance of the switched inductor array, which changes the operating frequency and other characteristics of the amplifier.

In accordance with another exemplary embodiment, a switched transformer array is provided that comprises at least two of the switched inductor arrays described above.

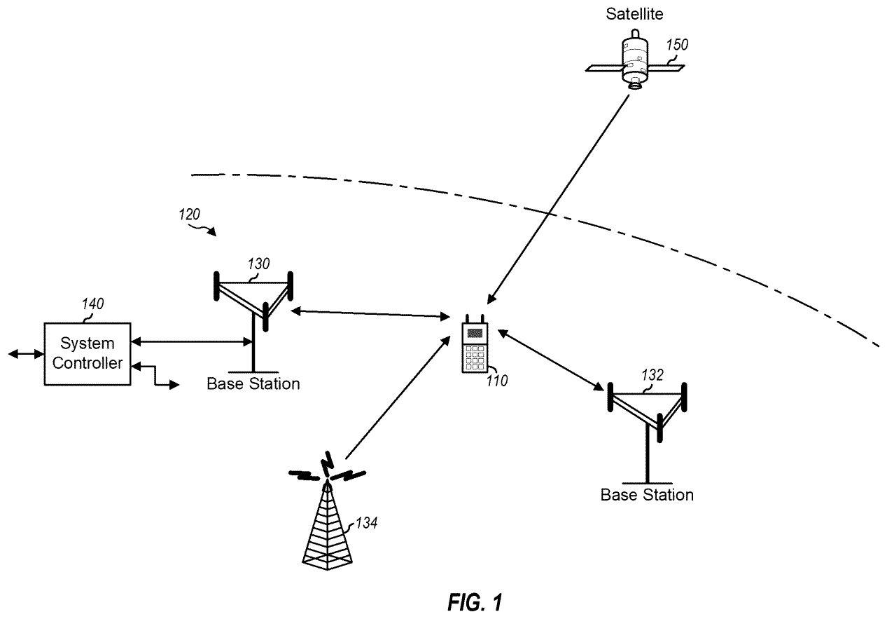

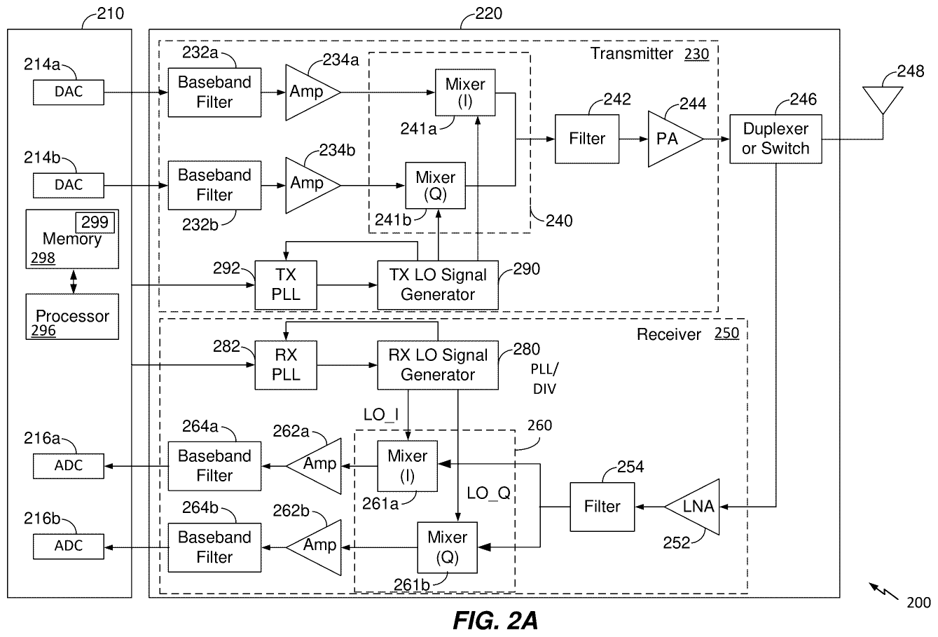

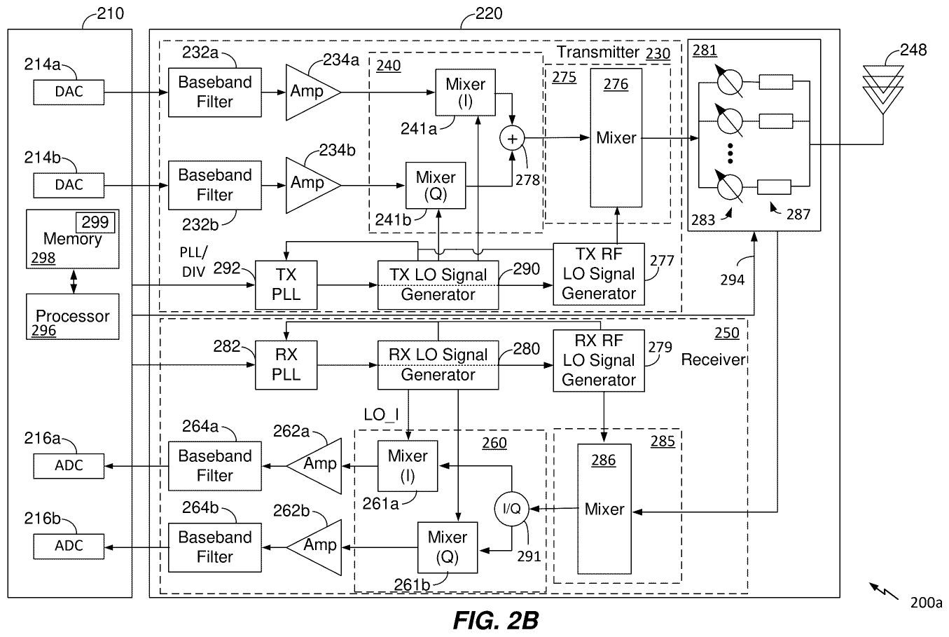

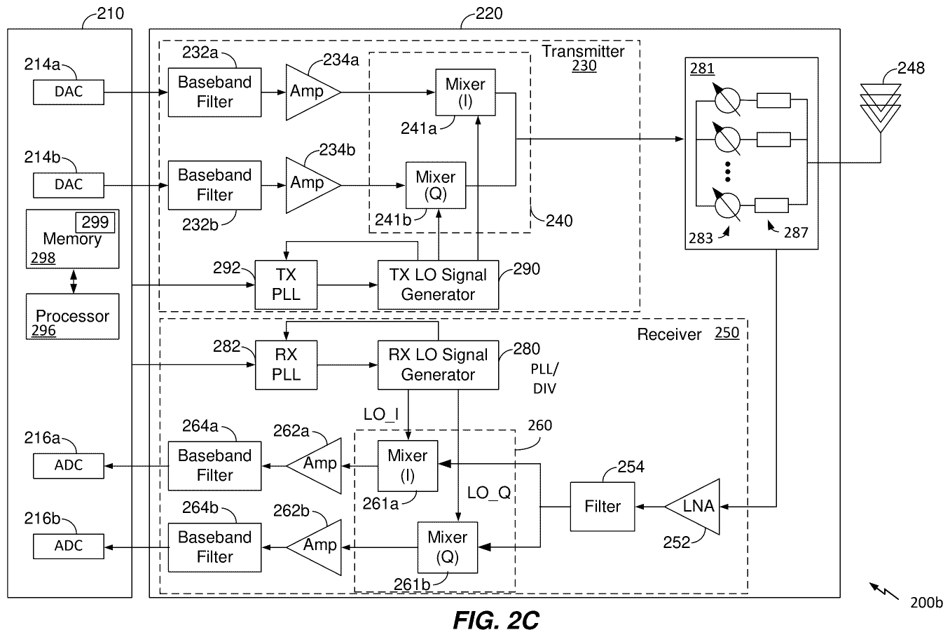

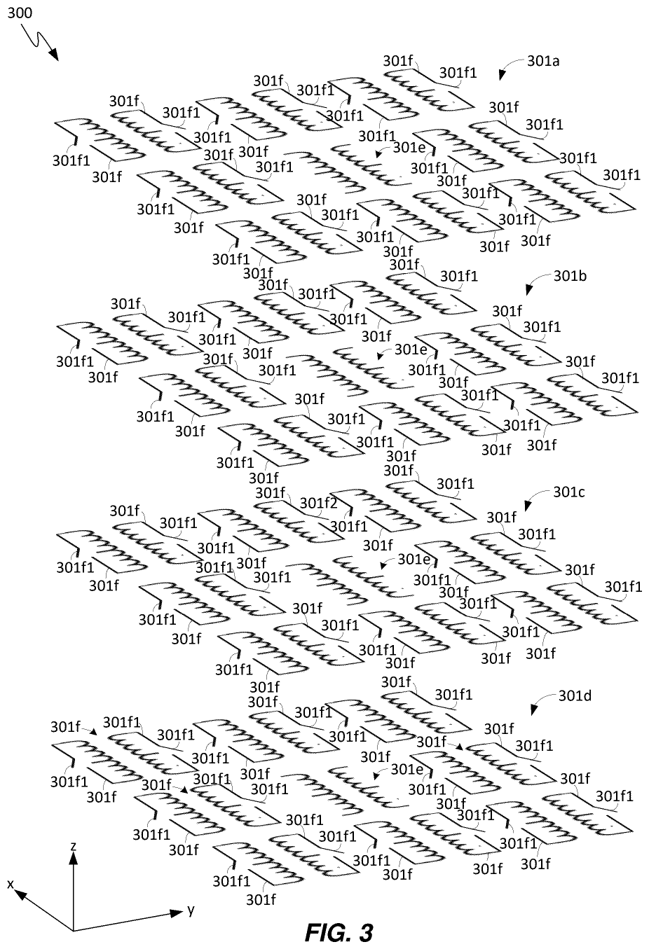

Exemplary embodiments of configurations, operations and attributes of the switched transformer and switched inductor arrays are described below with reference to FIGS. 3-14. Prior to describing those exemplary embodiments, examples of communications systems in which the switched transformer array may be used will be described with reference to FIG. 1-2C.

FIG. 1 is a diagram showing a wireless device 110 communicating with a wireless communication system 120. The wireless communication system 120 may be a Long Term Evolution (LTE) system, a Code Division Multiple Access (CDMA) system, a Global System for Mobile Communications (GSM) system, a wireless local area network (WLAN) system, a 5G NR (new radio) system, or some other wireless system. A CDMA system may implement Wideband CDMA (WCDMA), CDMA 1×, Evolution-Data Optimized (EVDO), Time Division Synchronous CDMA (TD-SCDMA), or some other version of CDMA. For simplicity, FIG. 1 shows wireless communication system 120 including two base stations 130 and 132 and one system controller 140. In general, a wireless communication system may include any number of base stations and any set of network entities.

The wireless device 110 may also be referred to as a user equipment (UE), a mobile station, a terminal, an access terminal, a subscriber unit, a station, etc. Wireless device 110 may be a cellular phone, a smartphone, a tablet, a wireless modem, a personal digital assistant (PDA), a handheld device, a laptop computer, a smartbook, a netbook, a tablet, a cordless phone, a medical device, an automobile, a device configured to connect to one or more other devices (for example through the internet of things), a wireless local loop (WLL) station, a Bluetooth device, etc. Wireless device 110 may communicate with wireless communication system 120. Wireless device 110 may also receive signals from broadcast stations (e.g., a broadcast station 134) and/or may communicate with satellites (e.g., a satellite 150 in one or more global navigation satellite systems (GNSS), or a satellite that can receive signals from the wireless device 110, etc.). Wireless device 110 may support one or more radio technologies for wireless communication such as LTE, WCDMA, CDMA 1×, EVDO, TD-SCDMA, GSM, 802.11, 802.15, 5G, Sub6 5G, 6G, UWB, etc.

Wireless device 110 may support carrier aggregation, for example as described in one or more LTE or 5G standards. In some embodiments, a single stream of data is transmitted over multiple carriers using carrier aggregation, for example as opposed to separate carriers being used for respective data streams. Wireless device 110 may be able to operate in a variety of communication bands including, for example, those communication bands used by LTE, WiFi, 5G or other communication bands, over a wide range of frequencies. Wireless device 110 may also be capable of communicating directly with other wireless devices without communicating through a network.

In general, carrier aggregation (CA) may be categorized into two types-intra-band CA and inter-band CA. Intra-band CA refers to operation on multiple carriers within the same band. Inter-band CA refers to operation on multiple carriers in different bands.

FIG. 2A is a block diagram showing a wireless device 200 in which exemplary techniques of the present disclosure may be implemented. The wireless device 200 may, for example, be an embodiment of the wireless device 110 illustrated in FIG. 1. A transceiver 220 of the wireless device 200 comprises a transmitter 230 and a receiver 250. In general, the conditioning of the signals in the transmitter 230 and the receiver 250 may be performed by one or more stages of amplifier, filter, upconverter, downconverter, etc. These circuit blocks may be arranged differently from the configuration shown in FIG. 2A. Furthermore, other circuit blocks not shown in FIG. 2A may also be used to condition the signals in the transmitter 230 and receiver 250. Unless otherwise noted, any signal in FIG. 2A, or any other figure in the drawings, may be either single-ended or differential. Some circuit blocks in FIG. 2A may also be omitted.

In the example shown in FIG. 2A, the wireless device 200 also comprises a data processor 210. The data processor 210 may include a processor 296 operatively coupled to a memory 298. The memory 298 may be configured to store data and program codes shown generally using reference numeral 299, and may generally comprise analog and/or digital processing components. The processor 296 and the memory 298 may cooperate to control, configure, program, or otherwise fully or partially control some or all of the operation of the embodiments of the pseudo bi-directional amplifier described herein.

The transceiver 220 includes a transmitter 230 and a receiver 250 that support bi-directional communication. In general, wireless device 200 may include any number of transmitters and/or receivers for any number of communication systems and frequency bands. All or a portion of the transceiver 220 may be implemented on one or more analog integrated circuits (ICs), RF ICs (RFICs), mixed-signal ICs, etc.

A transmitter or a receiver may be implemented with a super-heterodyne architecture or a direct-conversion architecture. In the super-heterodyne architecture, a signal is frequency-converted between radio frequency (RF) and baseband in multiple stages, e.g., from RF to an intermediate frequency (IF) in one stage, and then from IF to baseband in another stage for a receiver. In the direct-conversion architecture, a signal is frequency converted between RF and baseband in one stage. The super-heterodyne and direct-conversion architectures may use different circuit blocks and/or have different requirements. In the example shown in FIG. 2A, transmitter 230 and receiver 250 are implemented with the direct-conversion architecture.

In the transmit path, the data processor 210 processes data to be transmitted and provides in-phase (I) and quadrature (Q) analog output signals to the transmitter 230. In an exemplary embodiment, the data processor 210 includes digital-to-analog-converters (DAC's) 214a and 214b for converting digital signals generated by the data processor 210 into the I and Q analog output signals, e.g., I and Q output currents, for further processing. In other embodiments, the DACs 214a and 214b are included in the transceiver 220 and the data processor 210 provides data (e.g., for I and Q) to the transceiver 220 digitally.

Within the transmitter 230, baseband (e.g., lowpass) filters 232a and 232b filter the I and Q analog transmit signals, respectively, to remove undesired images caused by the prior digital-to-analog conversion. Amplifiers (Amp) 234a and 234b amplify the signals from baseband filters 232a and 232b, respectively, and provide I and Q baseband signals. An upconverter 240 having upconversion mixers 241a and 241b upconverts the I and Q baseband signals with I and Q transmit (TX) local oscillator (LO) signals from a TX LO signal generator 290 and provides an upconverted signal. A filter 242 filters the upconverted signal to remove undesired images caused by the frequency upconversion as well as noise in a receive frequency band. A power amplifier (PA) 244 amplifies the signal from filter 242 to obtain the desired output power level and provides a transmit RF signal. The transmit RF signal may be routed through a duplexer or switch 246 and transmitted via an antenna 248. While examples discussed herein utilize I and Q signals, those of skill in the art will understand that components of the transceiver may be configured to utilize polar modulation.

In the receive path, antenna 248 receives communication signals and provides a received RF signal, which may be routed through duplexer or switch 246 and provided to a low noise amplifier (LNA) 252. The duplexer 246 is designed to operate with a specific RX-to-TX duplexer frequency separation, such that RX signals are isolated from TX signals. The received RF signal is amplified by LNA 252 and filtered by a filter 254 to obtain a desired RF input signal.

Downconversion mixers 261a and 261b in a downconverter 260 mix the output of filter 254 with I and Q receive (RX) LO signals (i.e., LO_I and LO_Q) from an RX LO signal generator 280 to generate I and Q baseband signals. The I and Q baseband signals are amplified by amplifiers 262a and 262b and further filtered by baseband (e.g., lowpass) filters 264a and 264b to obtain I and Q analog input signals, which are provided to data processor 210. In the exemplary embodiment shown, the data processor 210 includes analog-to-digital-converters (ADC's) 216a and 216b for converting the analog input signals into digital signals to be further processed by the data processor 210. In some embodiments, the ADCs 216a and 216b are included in the transceiver 220 and provide data to the data processor 210 digitally.

In FIG. 2A, TX LO signal generator 290 generates the I and Q TX LO signals used for frequency upconversion, while RX LO signal generator 280 generates the I and Q RX LO signals used for frequency downconversion. Each LO signal is a periodic signal with a particular fundamental frequency. A phase locked loop (PLL) 292 receives timing information from data processor 210 and generates a control signal used to adjust the frequency and/or phase of the TX LO signals from LO signal generator 290. Similarly, a PLL 282 receives timing information from data processor 210 and generates a control signal used to adjust the frequency and/or phase of the RX LO signals from LO signal generator 280.

Wireless device 200 may support CA and may (i) receive multiple downlink signals transmitted by one or more cells on multiple downlink carriers at different frequencies and/or (ii) transmit multiple uplink signals to one or more cells on multiple uplink carriers. Those of skill in the art will understand, however, that aspects described herein may be implemented in systems, devices, and/or architectures that do not support carrier aggregation.

Certain components of the transceiver 220 are functionally illustrated in FIG. 2A, and the configuration illustrated therein may or may not be representative of a physical device configuration in certain implementations. For example, as described above, transceiver 220 may be implemented in various integrated circuits (ICs), RF ICs (RFICs), mixed-signal ICs, etc. In some embodiments, the transceiver 220 is implemented on a substrate or board such as a printed circuit board (PCB) having various modules, chips, and/or components. For example, the power amplifier 244, the filter 242, and the duplexer 246 may be implemented in separate modules or as discrete components, while the remaining components illustrated in the transceiver 220 may be implemented in a single transceiver chip.

The power amplifier 244 may comprise one or more stages comprising, for example, driver stages, power amplifier stages, or other components, that can be configured to amplify a communication signal on one or more frequencies, in one or more frequency bands, and at one or more power levels. Depending on various factors, the power amplifier 244 can be configured to operate using one or more driver stages, one or more power amplifier stages, one or more impedance matching networks, and can be configured to provide good linearity, efficiency, or a combination of good linearity and efficiency.

In an exemplary embodiment in a super-heterodyne architecture, the PA 244 and LNA 252 (and filter 242 and filter 254 in some examples) may be implemented separately from other components in the transmitter 230 and receiver 250, for example on a millimeter wave integrated circuit. An example super-heterodyne architecture is illustrated in FIG. 2B.

FIG. 2B is a block diagram showing a wireless device in which exemplary techniques of the present disclosure may be implemented. Certain components, for example which may be indicated by identical reference numerals, of the wireless device 200a in FIG. 2B may be configured similarly to those in the wireless device 200 shown in FIG. 2A and the description of identically numbered items in FIG. 2B will not be repeated.

The wireless device 200a is an example of a heterodyne (or superheterodyne) architecture in which the upconverter 240 and the downconverter 260 are configured to process a communication signal between baseband and an intermediate frequency (IF). The IF signal may be a low IF (LIF) signal, or a zero (or near zero) IF (ZIF) signal. For example, the upconverter 240 may include a summing function 278 and may be configured to provide an IF signal to an upconverter 275. In an exemplary embodiment, the upconverter 275 may comprise upconversion mixer 276. The summing function 278 combines the I and the Q outputs of the upconverter 240 and provides a non-quadrature signal to the upconversion mixer 276. The non-quadrature signal may be single ended or differential. The upconversion mixer 276 is configured to receive the IF signal from the upconverter 240 and TX RF LO signals from a TX RF LO signal generator 277, and provide an upconverted RF signal to phase shift circuitry 281. While PLL 292 is illustrated in FIG. 2B as being shared by the signal generators 290, 277, a respective PLL for each signal generator may be implemented.

In an exemplary embodiment, components in the phase shift circuitry 281 may comprise one or more adjustable or variable phased array elements, and may receive one or more control signals from the data processor 210 over connection 294 and operate the adjustable or variable phased array elements based on the received control signals.

In an exemplary embodiment, the phase shift circuitry 281 comprises phase shifters 283 and phased array elements 287. Although three phase shifters 283 and three phased array elements 287 are shown for ease of illustration, the phase shift circuitry 281 may comprise more or fewer phase shifters 283 and phased array elements 287. For example, one or two arrays of four or five antennas and corresponding phase shifters/phased array elements may be implemented.

Each phase shifter 283 may be configured to receive the RF transmit signal from the upconverter 275, alter the phase by an amount, and provide the RF signal to a respective phased array element 287. Each phased array element 287 may comprise transmit and receive circuitry including one or more filters, amplifiers, driver amplifiers, and/or power amplifiers. In some embodiments, respective phase shifters 283 may be incorporated within respective phased array elements 287 where each phased array element 287 will include a respective phase shifter 283.

The phase shift circuitry 281 is coupled to an antenna array 248. In an exemplary embodiment, the antenna array 248 comprises a number of antennas that typically correspond to the number of phase shifters 283 and phased array elements 287, for example such that each antenna element is coupled to a respective phased array element 287. In an exemplary embodiment, the phase shift circuitry 281 and the antenna array 248 may be referred to as a phased array.

In a receive direction, an output of the phase shift circuitry 281 is provided to a downconverter 285. In an exemplary embodiment, the downconverter 285 may comprise a downconversion mixer 286. In an exemplary embodiment, the mixer 286 downconverts the receive RF signal provided by the phase shift circuitry 281 to an IF signal according to RX RF LO signals provided by an RX RF LO signal generator 279. The downconverter 260 includes an I/Q generation function 291. The I/Q generation function 291 receives the IF signal from the mixer 286 and generates I and Q signals for the downconverter 260, which downconverts the IF signals to baseband, as described above. While PLL 282 is illustrated in FIG. 2B as being shared by the signal generators 280, 279, a respective PLL for each signal generator may be implemented.

In some embodiments, the upconverter 275, downconverter 285, and the phase shift circuitry 281 are implemented on a common IC. In some embodiments, the summing function 278 and the I/Q generation function 291 are implemented separate from the mixers 276 and 286 such that the mixers 276, 286 and the phase shift circuitry 281 are implemented on the common IC, but the summing function 278 and I/Q generation function 291 are not (e.g., the summing function 278 and I/Q generation function 291 are implemented in another IC coupled to the IC having the mixers 276, 286). In some embodiments, the LO signal generators 277, 279 are included in the common IC. In some embodiments in which phase shift circuitry is implemented on a common IC with 276, 286, 277, 278, 279, and/or 291, the common IC and the antenna array 248 are included in a module, which may be coupled to other components of the transceiver 220 via a connector. In some embodiments, the phase shift circuitry 281, for example, a chip on which the phase shift circuitry 281 is implemented, is coupled to the antenna array 248 by an interconnect or both are mounted to a substrate. For example, components of the antenna array 248 may be implemented on a substrate and coupled to an integrated circuit implementing the phase shift circuitry 281 via a flexible printed circuit or the integrated circuit may be mounted to an opposite side of the substrate.

In some embodiments, both the architecture illustrated in FIG. 2A and the architecture illustrated in FIG. 2B are implemented in the same device. For example, a wireless device 110 or 200 may be configured to communicate with signals having a frequency below about 7 GHz (e.g., FR1) using the architecture illustrated in FIG. 2A and to communicate with signals having a frequency above about 24 GHz (e.g., FR2 or higher) using the architecture illustrated in FIG. 2B. In devices in which both architectures are implemented, one or more components of FIGS. 2A and 2B that are identically numbered may be shared between the two architectures. For example, both signals that have been downconverted directly to baseband from RF and signals that have been downconverted from RF to baseband via an IF stage may be filtered by the same baseband filter 264. In other embodiments, a first version of the filter 264 is included in the portion of the device which implements the architecture of FIG. 2A and a second version of the filter 264 is included in the portion of the device which implements the architecture of FIG. 2B. While certain example frequencies are described herein, other implementations are possible. For example, signals having a frequency above about 24 GHz (e.g., having a mmW frequency) may be transmitted and/or received using a direct conversion architecture. In such embodiments, for example, a phased array may be implemented in the direct conversion architecture. Further, a wireless device may be configured to communicate with signals having a frequency between about 7 GHz and 24 GHz (e.g., FR3) using a phased array in a direct conversion architecture. In other examples, an intermediate frequency is used with FR3 signals.

FIG. 2C is a block diagram showing a wireless device in which exemplary techniques of the present disclosure may be implemented. Certain components, for example which may be indicated by identical reference numerals, of the wireless device 200b in FIG. 2C may be configured similarly to those in the wireless device 200 shown in FIG. 2A and/or the wireless device 200a shown in FIG. 2B and the description of identically numbered items in FIG. 2C will not be repeated.

The wireless device 200b in FIG. 2C incorporates the phase shift circuitry 281 (of FIG. 2B) in a direct conversion architecture, where mmW transmission signals are upconverted and downconverted between baseband and RF without the use of intermediate frequency (IF) signal conversion. For example, the LO signals in the architecture of FIG. 2C may comprise signals at frequencies of tens of GHz.

In some embodiments, the upconverter 240, downconverter 260, and the phase shift circuitry 281 are implemented on a common IC. In some embodiments, the LO signal generators 280, 290 are included in the common IC. In some embodiments, the common IC and the antenna array 248 are included in a module, which may be coupled to other components of the transceiver 220 via a connector. In some embodiments, the phase shift circuitry 281, for example, a chip on which the phase shift circuitry 281 is implemented, is coupled to the antenna array 248 by an interconnect or both are mounted to a substrate. For example, components of the antenna array 248 may be implemented on a substrate and coupled to an integrated circuit implementing the phase shift circuitry 281 via a flexible printed circuit or the integrated circuit may be mounted to an opposite side of the substrate.

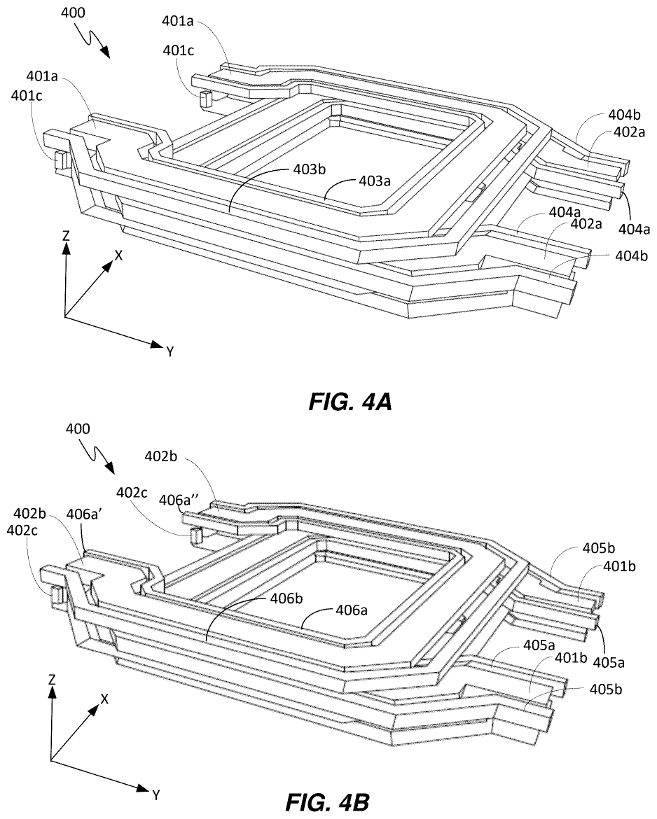

FIG. 3 shows a conceptual diagram of a switched transformer array 300 in accordance with an exemplary embodiment that may be employed in one or more of the devices of the systems shown in FIG. 1-2C, such as in, for example, the Amps 234a, 234b, 262a, 262b, the PA 244, the LNA 252 and/or in the phase shift circuitry 281. In the conceptual diagram shown in FIG. 3, the switched transformer array 300 comprises four subarrays 301a-301d, each of which includes a main transformer 301e and sixteen switched inductors 301f. For this conceptual diagram, the subarrays 301a-301d are depicted as being stacked vertically in the Z-direction of a Cartesian coordinate system and the main transformers 301e and the switched inductors 301f are depicted as having axes that are parallel to the X-axis of the Cartesian coordinate system. However, as will be described below in more detail with reference to, for example, FIGS. 4A and 4B, in accordance with an exemplary embodiment, the turns of the transformers 301e and the windings of the switched inductors 301f are typically formed in different metal layers of the BFIC that are spaced apart from one another in a direction that is generally perpendicular to the planes of the metal layers. Thus, if each metal layer of a BFIC lies in the X-Y plane of the Cartesian coordinate system, the switched inductors 301f and the main transformers 301e will typically have axes that are parallel to the Z-axis, with each individual turn or winding lying in the X-Y plane of the respective metal layer.

It should also be noted that although the switched inductors 301f are shown in the conceptual diagram of FIG. 3 symmetrically distributed about their respective main transformer 301e, such symmetry is not necessary, but may be preferred in some cases. It should also be noted that it is not necessary for the switched transformer array 300 to comprise subarrays 301a-301d, but the subarrays 301a-301d may be preferred in some cases. For example, in a broadband amplifier of a BFIC, one or more of the main transformers 301e may be disposed at the input and/or output of each stage, and each of the transformers may be coupled via electromagnet inductance to a respective array of the switched inductors 301f. A greater or few number of subarrays may be implemented.

In accordance with the exemplary embodiment of FIG. 3, each switched inductor 301f has a switch 301f1 that can be placed in an opened state or a closed state to turn the inductors 301f1 off and on, respectively. The switches 301f1 can have any suitable configuration. In an exemplary embodiment, the switches 301f1 comprise metal oxide semiconductor field effect transistors (MOSFETs) that are turned off or on by applying a voltage level corresponding to a digital 0 or a digital 1, respectively, to the gates of the respective MOSFETs. In cases where complementary metal oxide semiconductor (CMOS) process technology is used instead, CMOS transistors acting as the switches are turned off or on by applying a voltage level corresponding to a digital 1 or a digital 0, respectively, to the gates of the respective CMOS transistors.

Terminology used herein referring to the switches being placed in the opened state corresponds to the gates of MOSFET transistors being reversed biased and CMOS transistors being forward biased. Terminology used herein referring to the switches being placed in the closed state corresponds to the gates of MOSFET transistors being forward biased and CMOS transistors being reverse biased. The terms “asserted” and “deasserted” are used hereinafter to refer to a control bit having a value that causes a switch to be placed in an On state (closed) and an Off state (opened), respectively, regardless of the type of transistor that is used as the switch. Also, reference herein to a transistor operating as a switch can also mean multiple transistors connected together to operate as a single switch. Thus, a switch can comprise a configuration of multiple interconnected transistors. For ease of discussion, it will be assumed hereinafter that each switch comprises a single MOSFET or CMOS transistor that is turned off or on by deasserting or asserting, respectively, the control bit applied to the gate of the transistor. It should also be noted that the inventive principles and concepts are not limited to metal oxide or complementary metal oxide processes or devices made using those processes.

The switched inductors 301f are controlled by applying control bits to the switches 301f1. If the applied control bit is asserted, the respective switch 301f1 is closed, and vice versa. Closing one or more of the switches 301f2 and 301f4 of one or more of the switched inductors 301f has an inductive effect on the respective main transformers 301e that causes the electromagnetic inductance of the array 300 to change, resulting in a change in its operating frequency and other characteristics of the array.

The main transformers 301e of the subarrays 301a-301d can be in series with one another or in parallel with one another to achieve different frequencies of operation for the switched transformer array 300. For example, a parallel configuration of the main transformer arrays 301e can be achieved by connecting the center taps of the main transformer arrays 301e together using vias that extend between the metal layers of the BFIC. The width and the length of each switched inductor 301f and the spacing between each switched inductor 301f and its respective main transformer 301e affects the inductive coupling factors, the operating frequency, the quality factor, Q, the bandwidth (BW) and the inductance value, L, of the switched transformer array 300. Thus, any change to which of the switches 301f1 are turned on and off (by changing the values of the control bits) also affects all of these characteristics of the switched transformer array 300. In this way, selecting the control bit values that are applied in a predetermined manner causes the array 300 to behave in a predetermined manner to control the frequencies of the signals that are transmitted and received by a BFIC that incorporates the array 300. This obviates the need to use the aforementioned split architecture because a single switched transformer array 300 can be used to generate the entire range of frequencies by varying the control bit values in a predetermined manner. In addition, because the switches 301f1 of the switched inductors 300f are not in the signal path of the transformers 301e, the effect of switching loss on the performance of the transformers 301e is minimal.

FIG. 4A shows a top perspective view of a portion of a switched transformer array 400 formed in multiple metal layers of a BFIC (not shown) in accordance with an exemplary embodiment. FIG. 4B shows a bottom perspective view of the portion of a switched transformer array 400 shown in FIG. 4A flipped over, i.e., rotated by 180° about the X-axis. The portion of the array 400 shown in FIG. 4 shows the transformer and a plurality of switched inductors, but for ease of illustration, does not show the switches of the switched inductors. The transformer of this exemplary embodiment comprises a two-turn primary side and a two-turn secondary side, but the inventive principles and concepts are not limited in regard to the number of turns that make up the transformer.

A first turn 401a (FIG. 4A) of the primary side is formed in a first metal layer of an IC (e.g., a BFIC) and a second turn 401b (FIG. 4B) of the primary side is formed in a third metal layer of the IC. The first and second turns 401a and 401b, respectively, are interconnected by electrically-conductive vias 401c (FIG. 4A) that extend in between the first and third metal layers of the IC. A first turn 402a (FIG. 4A) of the secondary side is formed in a second metal layer of the IC and a second turn 402b (FIG. 4B) of the secondary side is formed in a fourth metal layer of the IC. The first and second turns 402a (FIGS. 4A) and 402b (FIG. 4B), respectively, are interconnected by electrically-conductive vias 402c (FIG. 4B).

Electrically-insulative layers (not shown) comprising a dielectric material, such as silicon dioxide, for example, are typically disposed in between the metal layers of the IC that are adjacent to one another to electrically insulate them from one another. Each of the turns 401a, 401b, 402a and 402b can be connected to a supply voltage at a center tap location of the turns 401a, 401b, 402a and 402b to provide a supply voltage of an electrical power domain of the IC to the switched transformer array 400.

In accordance with this exemplary embodiment each turn of the transformer is adjacent to first and second switched inductors. For example, first and second inductors 403a and 403b (FIG. 4A), respectively, extend along the length of the first turn 401a and are separated from the first turn 401a and from each other by preselected distances. First and second inductors 405a and 405b (FIG. 4B), respectively, extend along the length of the second turn 401b (FIG. 4B) of the primary side and are separated from the second turn 401b and from each other by preselected distances. First and second inductors 404a and 404b (FIG. 4A), respectively, extend along the length of the first turn 402a of the secondary side and are separated from the first turn 402a and from each other by preselected distances. First and second inductors 406a and 406b (FIG. 4B), respectively, extend along the length of the second turn 402b of the secondary side and are separated from the second turn 402b and from each other by preselected distances.

In accordance with the representative embodiment shown in FIGS. 4A and 4B, the first and second turns 401a, 401b, 402a and 402b have a first width and the inductors 403a, 403b, 404a, 404b, 405a, 405b, 406a and 406b have a second width that is smaller than the first width, but these width relationships are not a requirement of the present invention. Further, the inductors 403a, 403b, 404a, 404b, 405a, 405b, 406a and 406b need not have the same width. The inductors 403a, 403b, 404a, 404b, 405a, 405b, 406a and 406b are electrically isolated from one another and from the adjacent turns 401a, 401b, 402a and 402b alongside which they extend.

In accordance with this exemplary embodiment, opposite ends of each of the inductors 403a, 403b, 404a, 404b, 405a, 405b, 406a and 406b are interconnected by a switch 301f1 (FIG. 3). For example, opposite ends 406a′ and 406a″ (FIG. 4B) of inductor 406a are interconnected by a switch 301f1 (FIG. 3). However, in other embodiments, one or more of the inductors is a non-switched inductor. In this exemplary embodiment, opposite ends of the inductor 403a (FIG. 4A) are interconnected by a first switch that is not shown in FIG. 4A for ease of illustration. Opposite ends of the inductor 403b (FIG. 4A) are interconnected by a second switch that is not shown in FIG. 4A for ease of illustration. Opposite ends of the inductor 404a (FIG. 4A) are interconnected by a third switch that is not shown in FIG. 4A for ease of illustration. Opposite ends of the inductor 404b (FIG. 4A) are interconnected by a fourth switch that is not shown in FIG. 4A for ease of illustration. Opposite ends of the inductor 405a (FIG. 4B) are interconnected by a fifth switch that is not shown in FIG. 4B for ease of illustration. Opposite ends of the inductor 405b (FIG. 4B) are interconnected by a sixth switch that is not shown in FIG. 4B for ease of illustration.

Opposite ends of the inductor 406a (FIG. 4B) are interconnected by a seventh switch that is not shown in FIG. 4B for ease of illustration. Opposite ends of the inductor 406b (FIG. 4B) are interconnected by an eighth switch that is not shown in FIG. 4B for ease of illustration.

These switches can be turned on and off in the manner described above with reference to FIG. 3 by asserting and deasserting, respectively, the control bits that are applied to the switches to change the inductance of the switched transformer array 400, thereby changing the operating frequency and other characteristics of the switched transformer array 400. If the switched transformer array 400 is incorporated into, for example, a broadband amplifier, the primary side of the transformer comprising turns 401a (FIGS. 4A) and 401b ((FIG. 4B) can be connected to the drain of a cascode differential pair of the amplifier and the secondary side comprising turns 402a (FIGS. 4A) and 402b (FIG. 4B) can be connected to the input of the next stage of the amplifier. In such configurations, changing which of the switches are turned off or on changes the inductance of the switched transformer array 400, which changes the operating frequency and other characteristics of the amplifier.

Vertically interleaving the secondary turns 402a and 402b with the primary turns 401a and 401b is not necessary, but can be advantageous in that it provides double broadside inductive coupling, which increases the inductive coupling coefficient of the transformer. There is a trade-off between switching range and coupling coefficients that depends on which layer and which inductor is assigned to be the transformer or switching elements. The turns 401a, 401b, 402a, 402b can be stacked and aligned in the Z-direction or shifted relative to one another in the X and/or Y directions. The decision is based on the amount of coupling required between the turns, which also has an impact on the achievable range and frequency response.

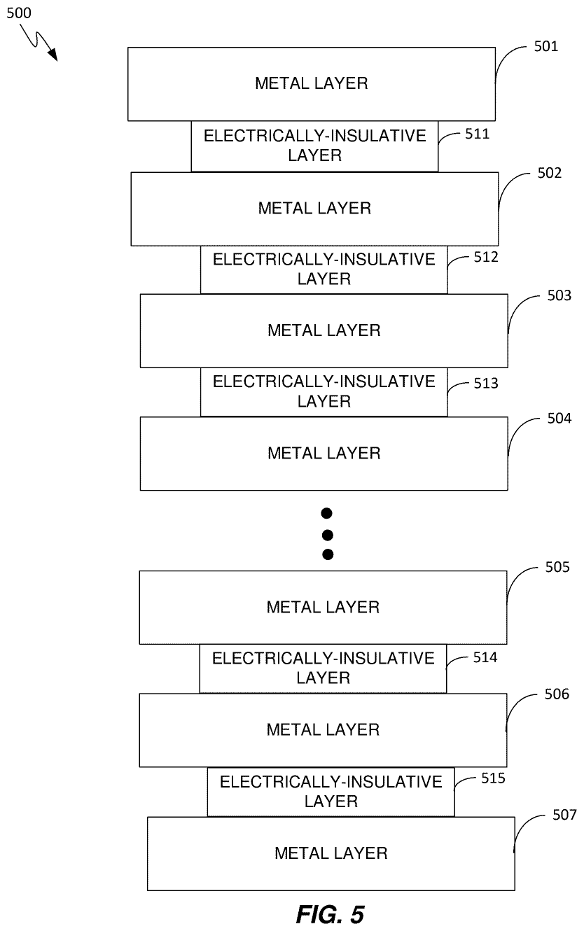

FIG. 5 is a side cross-sectional view of a metal stack 500 comprising the switched transformer array 400 shown in FIGS. 4A and 4B in accordance with an exemplary embodiment. The metal stack 500 in which the switched transformer array 400 is formed can be constructed using various IC fabrication processes that are known to those of skill in the art. The inventive principles and concepts are not limited in regard to the process that is used to form the metal stack 500. In accordance with this exemplary embodiment, the metal stack 500 comprises a plurality of metal layers 501 - 507 and a plurality of electrically-insulative layers 511-515. Each of the metal layers 501-507 can comprise one or more metals, such as aluminum and copper, for example. Each of the electrically-insulative layers 511-515 can comprise one or more dielectric materials, such as silicon dioxide, for example.

In accordance with the exemplary embodiment described above with reference to FIGS. 4A and 4B, the turns 401a and 401b of the primary side of the transformer are formed in the first and third metal layers 501 and 503, respectively, of the metal stack 500 shown in FIG. 5, and the turns 402a and 402b of the secondary side of the transformer are formed in the second and fourth metal layers 502 and 504, respectively, of the metal stack 500 shown in FIG. 5. Additional transformer turns can be formed in additional metal layers of the metal stack 500, such as in metal layers 505-507, for example.

Electrically-insulative layer 511 is disposed in between metal layers 501 and 502. Electrically-insulative layer 512 is disposed in between metal layers 502 and 503. Electrically-insulative layer 513 is disposed in between metal layers 503 and 504. The inductors 403a and 403b are formed in the first metal layer 501. The inductors 404a and 404b are formed in the second metal layer 502. The inductors 405a and 405b are formed in the third metal layer 503. The inductors 406a and 406b are formed in the fourth metal layer 504. Any suitable processes can be used to form the transformer turns and the inductor windings in the metal layers. Different processes exist for patterning metal layers that can be used for this purpose, as is understood by persons of skill in the art. Therefore, in the interest of brevity, such processes will not be described herein.

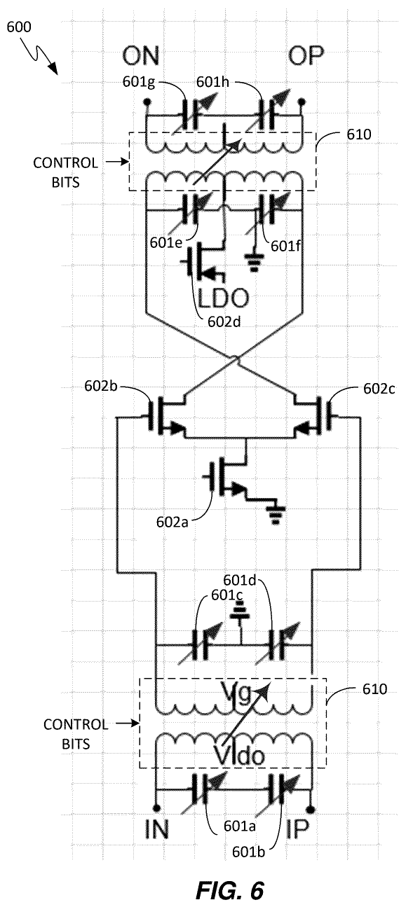

As indicated above, the switched transformer arrays can be used in a variety of communications devices such as those shown in FIG. 1-2C, for example. FIG. 6 is a block diagram of a portion of a cascade amplifier 600 that incorporates switched transformer arrays 610 of the present disclosure. The transformer primary or secondary side of the switched transformer array 610 is connected to an electrical node of the amplifier 600, i.e., to the drain or source of a MOSFET of the amplifier 600. The switched transformer array 610 can have the configuration shown in FIGS. 4A and 4B or similar configurations. The amplifier 600 has a common source configuration and can be, for example, a driver amplifier (DA), a low noise amplifier (LNA) or a power amplifier (PA). The amplifier 600 includes MOSFETs 602b, 602c having gates coupled to differential outputs of a first one of the transformers 610. Sources of the MOSFETs 602b, 602c are coupled to ground via a MOSFET 602a. Variable capacitors 601c, 601d are coupled between the outputs of the first one of the transformers 610 and are coupled to ground. Variable capacitors 601a, 601b are coupled between differential inputs of the first one of the transformers 610. Drains of the MOSFETs 602b, 602c are coupled to differential inputs of a second one of the transformers 610. Variable capacitors 601g, 601h are coupled between the outputs of the second one of the transformers 610. Variable capacitors 601e, 601f are coupled between differential inputs of the first one of the transformers 610. The switched transformer arrays 610 operate in the manner described above with reference to FIG. 3-4B, i.e., as preselected combinations of control bit values are applied to the switches of the switched transformer arrays 610, the operating frequency of the amplifier 600 changes accordingly.

In the example shown in FIG. 6, the center taps of the primary sides and secondary sides of the switched transformer array 610 at the input stage of the amplifier 600 are connected to the gate voltage, Vg, and the low dropout (LDO) voltage of a low dropout voltage regulator, Vldo, respectively. The center taps of the primary sides and secondary sides of the switched transformer array 610 at the output stage of the amplifier 600 can be similarly connected. The gates of MOSFETs 602a and 602d are connected to a switching voltage to switch the MOSFETs 602a and 602d off and on. The terminals IN and IP are connected to the output terminals of the previous stage or an input (not shown) of the amplifier 600. The terminals ON and OP are connected to the input terminals of the next stage or an output (not shown) of the amplifier 600.

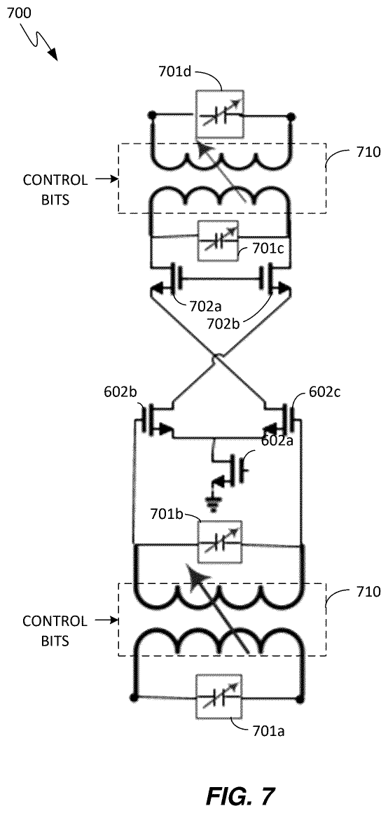

FIG. 7 is a block diagram of an amplifier 700 that incorporates a switched transformer array 710 of the present disclosure. The switched transformer array 710 can have the configuration shown in FIGS. 4A and 4B or similar configurations. The transformer primary or secondary side of the switched transformer array 710 is connected to an electrical node of the amplifier 700, i.e., to the drain or source of a MOSFET of the amplifier 700. The amplifier 700 has a cascode configuration and can be, for example, a DA, an LNA or a PA. The amplifier 700 has a configuration of circuit elements similar to that shown in FIG. 6, except that the amplifier 700 has additional MOSFETs 702a and 702b comprising a cascode pair. In addition, the amplifier 700 includes variable capacitors 701a-701d and MOSFETs 602a-602c. The switched transformer arrays 710 operate in the manner described above with reference to FIG. 3-4B, i.e., as preselected combinations of control bit values are applied to the switches of the switched transformer arrays 710, the operating frequency of the amplifier 700 changes accordingly.

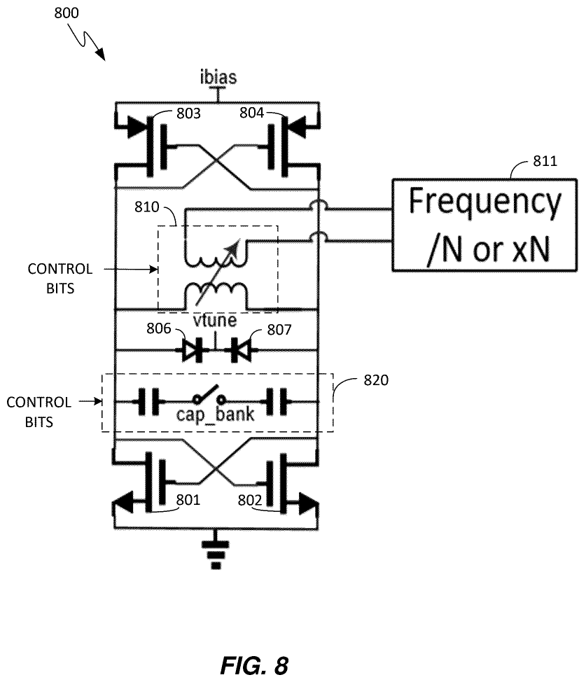

FIG. 8 is a block diagram of a voltage-controlled oscillator (VCO) 800 that incorporates a switched transformer array 810 of the present disclosure. The switched transformer array 810 can have the configuration shown in FIGS. 4A and 4B or similar configurations. The VCO 800 also incorporates a switched capacitor array 820. Switched capacitor arrays have been widely used in wireless communication transceivers, but they may have a limited tuning range and the Q factor may drop as the capacitance increases, which prohibits broadband operation. Often, the hardware of the switched capacitor array requires multi-band signal paths, which doubles or triples the silicon area of the BFIC compared to the single signal path that is made possible through the use of the switched transformer arrays of the present disclosure. Simultaneous deployment of the switched transformer array 810 and the switched capacitor array 820 in a communications device such as, for example, the VCO 800 shown in FIG. 8 or the amplifiers 600 and 700 shown in FIGS. 6 and 7, respectively (e.g., in place of or in addition to any of the variable capacitors 601 or 701), allows extremely broadband BFICs to be configured that overcome the limitations of switched capacitor arrays and that are capable of FHSS for 5G/6G security networks.

The VCO 800 includes MOSFETs 801-804, and diodes 806 and 807, and has outputs coupled to frequency divider and/or frequency multiplier circuitry 811. MOSFETs 803, 804 have gates coupled to differential inputs of the switched transformer array 810. Sources of the MOSFETs 803, 804 are coupled to a bias current, ibias, terminal. Drains of MOSFETs 803 and 804 are (cross) coupled to gates of MOSFETs 804 and 803, respectively (and to the differential inputs of the switched transformer array 810). MOSFETs 801, 802 have gates coupled to differential outputs of the switched capacitor array 820. Input of the VCO 800 may be coupled to the switched capacitor array 820. Sources of the MOSFETs 801, 802 are coupled to ground. Drains of MOSFETs 801 and 802 are (cross) coupled to gates of MOSFETs 802 and 801, respectively. Tuning diodes 806 and 807 have anodes that are coupled to the differential outputs of switched transformer array 810 and cathodes that are coupled to a tuning voltage, vtune, terminal. Differential outputs of the switched transformer array 810 are coupled to differential inputs of the frequency divider or multiplier 811.

The switched transformer array 810 operates in the manner described above with reference to FIG. 3-4B in coordination with the operations of the switched capacitor array 820. As preselected combinations of control bit values are applied to the switches of the switched transformer arrays 810 and to the switches of the switched capacitor array 820, the operating frequency of the VCO 800 changes accordingly, while overcoming the aforementioned limitations of the current switched capacitor array configurations used without the switched transformer array 810.

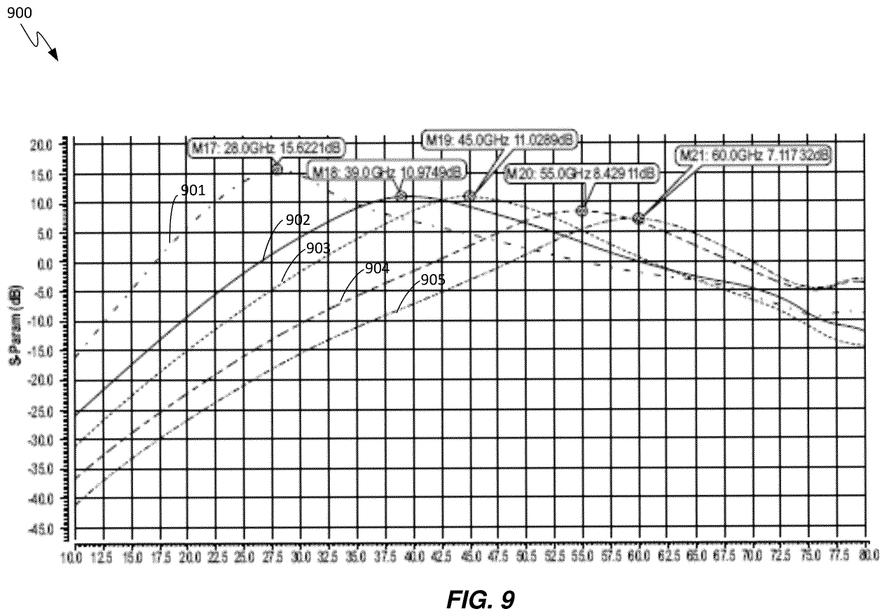

FIG. 9 shows a group of plots 900 of the frequency responses of a PA that can have the configuration shown in FIG. 6 or 7, which incorporate the switched transformer arrays 610 or 710 shown in FIG. 6 or 7 that can have the configurations shown in FIGS. 4A and 4B, or similar configurations. The plots 901, 902, 903, 904 and 905 show the gain of the PA 600 or 700 vs. frequency of the PA for five different settings of the switched transformer arrays 610, 710, i.e., for five different sets of control bit values being applied to the switches of the inductors of the arrays 610, 710. For exemplary purposes, only five plots are shown for five different sets of control bits, but the number of different frequencies that can be produced using the arrays 610, 710 will depend on the number of switched inductors that are used, which can vary depending on the design.

For the exemplary embodiment shown in FIG. 9, the first plot 901 has a center frequency of 28.0 GHz with a gain of 15.622 decibels (dB). The second plot 902 has a center frequency of 39.0 GHz with a gain of 10.974 dB. The third plot 903 has a center frequency of 45.0 GHz with a gain of 11.028 dB. The fourth plot 904 has a center frequency of 55.0 GHz with a gain of 8.429 dB. The fifth plot 905 has a center frequency of 60.0 GHz with a gain of 7.117 dB.

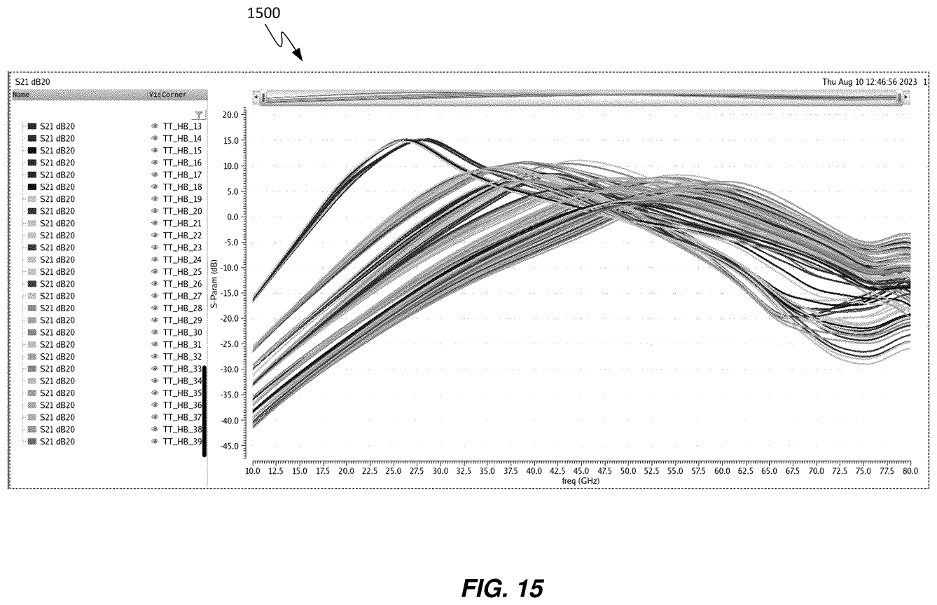

It can be seen from the group of plots 900 that incorporation of the switched transformer arrays 610 into the PA 600 allows the entire FR2 frequency range to be covered with very high output power in a very small silicon area in the BFIC. This amount of output power cannot currently be achieved using the aforementioned split architectures, even in the larger silicon areas that they require for the signal paths. As will be described below in more detail with reference to FIG. 15, switched capacitor arrays (FIG. 8) can be used in combination with the switched transformer arrays 610, 710 to fill in the frequency gaps between the center frequencies of plots 901-905 with fine steps. In other words, the switched transformer arrays 610, 710 can be used to provide coarse tuning and the switched capacitor arrays can be used to provide fine tuning. For example, tuning with a switched transformer array (e.g., 610, 710) can be on the order of GHz, while tuning with a switched capacitor array can be on the order of (tens or hundreds, in some configurations, of) MHz. In addition, spread spectrum frequency hopping can be performed with great agility by applying preselected sets of control bits to the switches on the transmitter and receiver ends of a communications link, which is useful for security applications as well as for broadband code division multiple access (CDMA) communications.

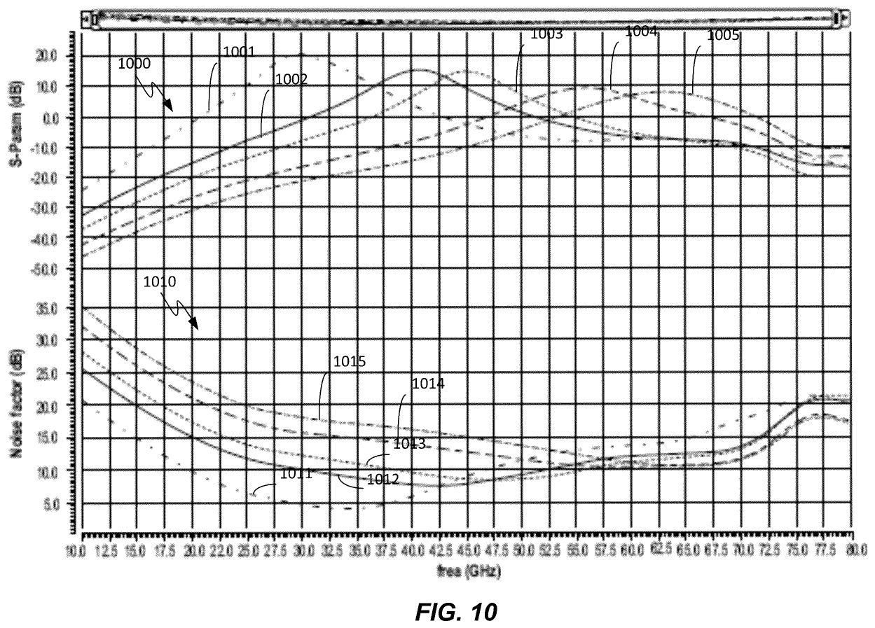

FIG. 10 shows groups of plots 1000 and 1010 of gain vs. frequency and noise factor (NF) vs. frequency, respectively, for an LNA having the configurations shown in FIG. 6 or 7 that incorporate the switched transformer arrays 610 or 710 shown in FIG. 6 or 7, respectively. The plots 1001, 1002, 1003, 1004 and 1005 show the gain vs. frequency of the LNA for five different settings of the switched transformer arrays 610 or 710 corresponding to five different sets of control bit values being applied to the switches of the inductors of the arrays 610 or 710. For exemplary purposes, only five plots are shown for five different sets of control bits, but the number of different frequencies that can be produced using the arrays 610 or 710 will depend on the number of switched inductors that are used, which can vary depending on the design.

For the exemplary embodiment shown in FIG. 10, the first plot 1001 has a center frequency of about 30.0 GHz with a gain of about 20 dB, which corresponds to an NF on plot 1011 of about 4 dB. The second plot 1002 has a center frequency of about 40.0 GHz with a gain of about 14 dB, which corresponds to an NF on plot 1012 of about 7 dB. The third plot 1003 has a center frequency of about 45.0 GHz with a gain of about 13 dB, which corresponds to an NF on plot 1013 of about 7 dB. The fourth plot 1004 has a center frequency of 56.0 GHz with a gain of about 10 dB, which corresponds to an NF on plot 1014 of about 10 dB. The fifth plot 1005 has a center frequency of about 62.0 GHz with a gain of about 8 dB, which corresponds to an NF on plot 1015 of about 11 dB.

It can be seen from FIG. 10 that incorporation of the switched transformer arrays 610 or 710 into the LNA 600 or 700 allows the entire FR2 frequency range to be covered with releatively high gain and relatively low NF. As indicated above, this can be accomplished in a very small silicon area in the BFIC compared to the amount of silicon area required for the aforementioned split architecture. Switched capacitor arrays (FIG. 8) can be used in combination with the switched transformer arrays 610 or 710 to fill in the frequency gaps between the maximum-gain frequencies of plots 1001-1005 with fine steps to perform fine frequency tuning. This allows the LNA to be used to perform spread spectrum frequency hopping with great agility by applying preselected sets of control bits to the switches on the transmitter and receiver ends of a communications link for security applications as well as for broadband CDMA communications.

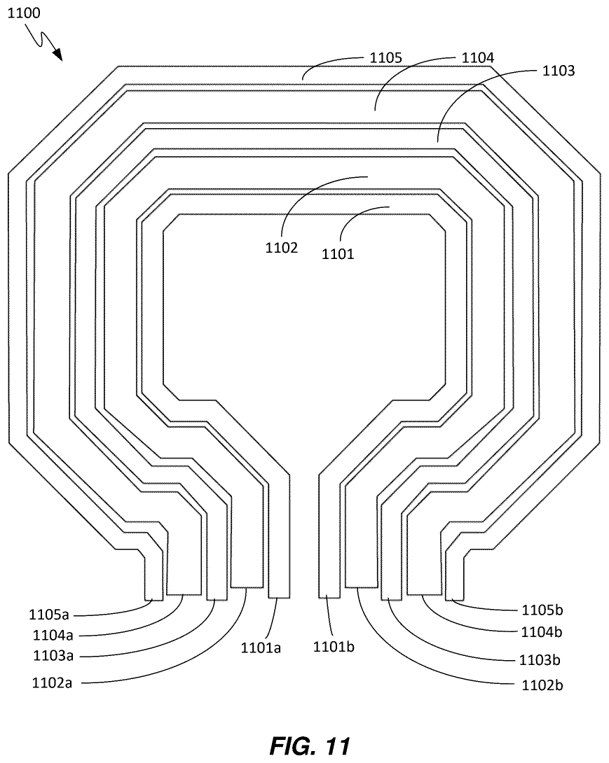

FIG. 11 shows a portion of a switched inductor array in accordance with an exemplary embodiment. The portion of the array shown is an N−strand inductor comprising N inductor strands 1101-1105 that are generally circular in shape and concentrically oriented in at least a first metal layer of a BFIC, where N is a positive integer that is greater than or equal to two. In accordance with this exemplary embodiment, N=5. N−1 of the inductor strands can be switched inductor strands that include respective switches (not shown) that can be placed in an opened state or a closed state to turn the respective inductor strands off and on, respectively. At least one of the inductor strands is a non-switched inductor strand.

In this example, inductor strands 1101, 1102, 1104 and 1105 are switched inductor strands and inductor strand 1103, which is the center inductor strand, is a non-switched inductor strand. The inductor strand 1103 operates as the primary turn of a transformer. If the switched inductor array is incorporated into, for example, an amplifier of a BFIC, the ends 1103a and 1103b of the non-switched inductor strand 1103 can be connected to, for example, the drain of a cascode differential pair of the amplifier, such as that shown in FIG. 7.

The ends 1101a and 1101b of inductor strand 1101 would be connected to the source and drain, respectively, of a first MOSFET switch (not shown). The ends 1102a and 1102b of inductor strand 1102 would be connected to the source and drain, respectively, of a second MOSFET switch (not shown). The ends 1104a and 1104b of inductor strand 1104 would be connected to the source and drain, respectively, of a third MOSFET switch (not shown). The ends 1105a and 1105b of inductor strand 1105 would be connected to the source and drain, respectively, of a fourth MOSFET switch (not shown).

In such a configuration, asserting and deasserting the control bits that are applied to the gates of the MOSFET switches turns the switched inductor strands 1101, 1102, 1104 and 1105 on and off, respectively. which changes the inductance of the switched inductor array, thereby changing the operating frequency and other characteristics of the amplifier. As noted above, other types of switches may be utilized.

In accordance with another exemplary embodiment, the switched inductor array comprises N inductor strands that are concentrically formed in a first metal layer of a BFIC and N inductor strands that are concentrically formed in a second metal layer of a BFIC, where N is an odd-number integer that is greater than or equal to three. N−1 of the inductor strands (four strands in the example of FIG. 11) in the first and second metal layers can be switched inductor strands that include N−1 switches, respectively, that can be placed in an opened state or a closed state to turn the respective switched inductor strand off and on, respectively.

At least the #(N+1)/2 inductor strand in the first and second metal layers can be a non-switched inductor strand, which is the center strand 1103 in the example shown in FIG. 11. In the second metal layer, the #(N+1)/2 inductor strand can operate as the secondary side transformer turn. If the switched inductor array is incorporated into, for example, an amplifier of a BFIC, the ends of the #(N+1)/2 non-switched inductor strand of the primary side (the first metal layer) can be connected to the drain of a cascode differential pair of the amplifier and the ends of the #(N+1)/2 non-switched inductor strand of the secondary side (the second metal layer) can be connected to the next stage of the amplifier. In such a configuration, turning the switched inductors off or on changes the inductance of the switched inductor array, which changes the operating frequency and other characteristics of the amplifier.

In accordance with another exemplary embodiment, multiple switched inductor arrays of the type shown in FIG. 11 are stacked vertically in the BFIC to form a stacked switched inductor array. The stacked switched inductor arrays can be offset, or shifted, laterally relative to one another based on the desired electromagnetic coupling characteristics and/or response. In accordance with another exemplary embodiment, the switched inductor array 1100 shown in FIG. 11 is formed in the top metal layer of the metal stack and the switched transformer array 400 is formed in the second, third, fourth and fifth metal layers of the metal stack. The inductor strands within a layer may be uniform in width, or may vary. For example, in the configuration illustrated in FIG. 11, the strands alternate in width. Further, the inductors strands may be uniform in width across layers in the stack or may vary. The distance (spacing) between inductor strands within a layer may be uniform, or may vary. Further, distance between inductor strands may be uniform across layers in the stack or may vary. Any of the arrays can be connected in series in the metal stack to increase the overall inductance of the combination.

This combination array incorporated into an amplifier such as an LNA achieved a frequency range of about 8 GHz to 16 GHz with a relatively high gain and relatively low NF. Thus, the combination covers the 5G mmWave X-Band, the Ku-Band and the X/Ku-Band. At a center frequency of about 8 GHz, the gain was about 12 dB and the NF was about 3.3 dB. At a center frequency of about 10 GHz, the gain was about 19.4 dB and the NF was about 2.3 dB. At a center frequency of about 12 GHz, the gain was about 22 dB and the NF was about 2.5 dB. At a center frequency of about 14 GHz, the gain was about 16 dB and the NF was about 3.8 dB. At a center frequency of about 16 GHz, the gain was about 15 dB and the NF was about 3.8 dB.

For the array 400 shown in FIGS. 4A and 4B, the primary side of the transformer comprising turns 401a (FIGS. 4A) and 401b ((FIG. 4B) can be connected to the drain of a cascode differential pair of the amplifier and the secondary side comprising turns 402a (FIGS. 4A) and 402b (FIG. 4B) can be connected to the input of the next stage or output of the amplifier. For the array 1100, the ends 1103a and 1103b of the non-switched inductor 1103 can be connected to the drain of a cascode differential pair of the amplifier.

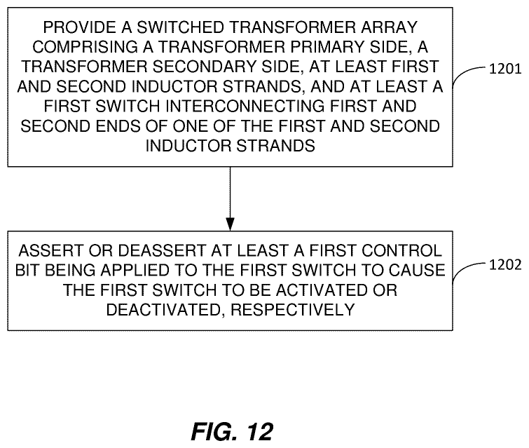

FIG. 12 is a flow diagram representing a method in accordance with an exemplary embodiment for using a switched transformer array to change an operating frequency of beamformer circuitry of a BFIC. Block 1201 represents the step of providing a switched transformer array comprising a transformer primary side, a transformer secondary side, at least first and second inductor strands, and at least a first switch. Block 1202 represents the step of asserting or deasserting at least a first control bit being applied to at least the first switch of the swiched transformer array to cause the first switch to be activated or deactivated, respectively. The first switch interconnects first and second ends of one of the first and second inductor strands. Activation and deactivation of the first switch changes electromagnetic inductive characteristics of the switched transformer array, thereby changing an operating frequency of the switched transformer array.

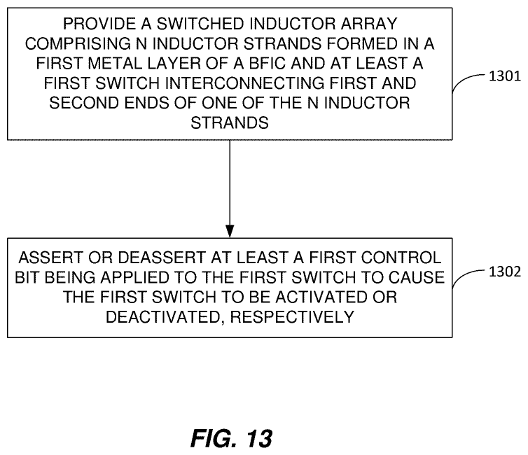

FIG. 13 is a flow diagram representing a method in accordance with an exemplary embodiment for using a switched inductor array to change an operating frequency of beamformer circuitry of a BFIC. Block 1301 represents the step of providing a switched inductor array comprising N inductor strands and at least a first switch interconnecting first and second ends of one of the N inductor strands, where N is a positive integer that is greater than or equal to 3. The N inductor strands are formed in a first metal layer of the BFIC preselected distances from one another. The preselected distances are preselected to ensure electromagnetic inductive coupling between at least adjacent inductor strands when electrical current passes through the inductor strands.

Block 1302 represents the step of asserting or deasserting at least a first control bit applied to at least the first switch of the swiched inductor array to cause the first switch to be activated or deactivated, respectively. Activation and deactivation of the first switch changes electromagnetic inductive characteristics of the switched transformer array, thereby changing an operating frequency of the switched transformer array.

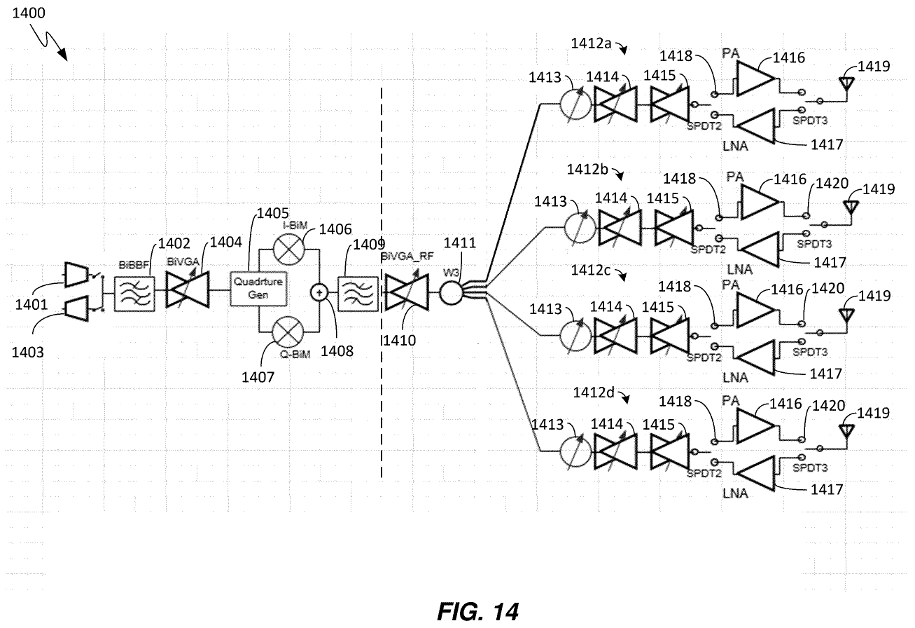

FIG. 14 shows a block diagram of a wireless communications system 1400 in accordance with an exemplary embodiment that incorporates one or more instances of the switched transformer array of the present disclosure. In accordance with this exemplary embodiment, the wireless communications system 1400 is configured to operate as a bidirectional wireless transceiver. In other examples, separate transmit and receive functionality may be implemented at one or more locations in the system 1400, for example as illustrated with respect to FIGS. 2A-2C.

An analog-to-digital converter (ADC) 1401 has an input terminal that is coupled to a first output terminal of a first bidirectional baseband filter (BiBBF) 1402 and an output terminal that outputs a digital signal representative of a wireless signal received by the system 1400. A first input terminal of the BiBBF 1402 is coupled to an output terminal of a digital-to-analog converter (DAC) 1403. For example, the ADC 1401 and/or the DAC 1403 maybe implemented in the data processor 210 or coupled to the data processor 210. Respective input and output terminals of certain components are described herein, such as the first output terminal and the first input terminal of the BiBBF 1402. In some examples, the input terminal and output terminal on the same “side” (e.g., the downstream “side” or the upstream “side”) of a component may be the same (e.g., a common) terminal. For example, the first output terminal and the first input terminal of the BiBBF 1402 may be the same first common terminal, and/or the second output terminal and the second input terminal (described below) of the BiBBF 1402 may be the same second common terminal (which is different than the first common terminal).

Second input and output terminals of the BiBBF 1402 are coupled to first output and input terminals, respectively, of a first bidirectional variable gain amplifier (BiVGA) 1404. Second input and output terminals of the BiVGA 1404 are coupled to terminals of a quadrature generator 1405 having terminals that are coupled to an in-phase signal bidirectional mixer (I-BiM)1406 that performs frequency up conversion and down conversion. The quadrature generator 1405 has terminals that are coupled to a quadrature signal bidirectional mixer (Q-BiM)1407 that performs frequency up conversion and down conversion. Terminals of the I-BiM 1406 and of the Q-BiM 1407 are coupled to a combiner 1408 having terminals that are coupled to a second filter 1409. In some examples, the mixers 1406, 1407 are implemented with multiple stages or multiple mixers (for example, to implement a direct conversion architecture or a super-heterodyne or intermediate frequency architecture).

Input and output terminals of the filter 1409 are coupled to output and input terminals, respectively, of a second BiVGA 1410. Input and output terminals of the BiVGA 1410 are coupled to terminals of a splitter/combiner 1411 having terminals that are coupled to signal processing paths 1412a-1412d. Four signal processing paths 1412a-1412d are shown in FIG. 14 for exemplary purposes and for ease of illustration. It should be noted, however, that the system 1400 may have any number, N, of signal processing paths, where N is a positive integer. The signal processing paths 1412a-1412d may have identical configurations for performing beam forming, with each signal processing path 1412a-1412d including a phase shifter 1413 and biVGAs 1414, optionally 1415, a PA 1416 (which may include or be coupled to a driver amplifier, not shown), a LNA 1417, a switching circuit 1418, and a switching circuit 1420. An antenna 1419 may be coupled to each signal processing path 1412.

Elements illustrated on the right side of the vertical dotted line (with the exception of the antennas 1419) may be implemented on a single BFIC. In some examples, one or more mixers (for example, configured to convert between an intermediate frequency and a radio frequency) are also included on the BFIC.

Each of the antennas 1419 may be configured for use and/or can be tuned to be used over a wide band, for example encompassing multiple communication bands. For example, each of the antennas 1419 may be configured to receive and/or transmit signals over a band of approximately 10 GHz, 20 GHz, 30 GHz, or more. In some examples, each of the antennas 1419 are configured for use and/or can be tuned to be used over the entire FR2 range.

In some examples, additional antennas (not illustrated) are implemented and couplable to the signal processing paths 1412, for example to support additional bands and/or bandwidth. In one example, the antennas 1419 are configured to communicate in the FR2a band, and additional antennas are included which are configured to communicate in the FR2b and FR2c bands. The switching circuits 1420 may be configured to selectively couple the signal processing paths 1412 to the antennas 1419 or to the additional antennas.

The switched transformer arrays of the present disclosure may act as the load of an amplifier or as the input impedance matching network of an amplifier. Embodiments of the switched transformer array of the present disclosure may be employed in, for example, the BiVGAs 1404, 1410, 1414, 1415, the PAs 1416, and/or the LNAs 1417, e.g., at an input or output of these amplifiers, or between amplification stages within these amplifiers. As can be appreciated based on the description herein, the switched transformer arrays described herein may be advantageous in either bidirectional components or unidirectional components.

In the transmit direction, DAC 1403 converts digital signal generated by a data processor (not shown in FIG. 14) into an analog signal, e.g., an output current. BiBBF 1402 (e.g., lowpass) filters the analog transmit signal to remove undesired images caused by the prior digital-to-analog conversion. BiVGA 1404 amplifies the filtered analog signal output from BiBBF 1402 and provides it to the quadrature generator 1405, which generates I and Q baseband signals. The I-BiM 1406 and the Q-BiM 1407 mix the I and Q baseband signals, respectively, with I and Q transmit LO signals to frequency-upconvert the signals. The combiner 1408 combines the frequency-upconverted signals to produce a combined upconverted signal. The filter 1409 filters the upconverted signal to remove undesired images caused by the frequency upconversion as well as noise in a receive frequency band.

The BiVGA 1410 amplifies the signal output from filter 1409 to obtain a transmit RF signal having a desired output power level and provides it to splitter/combiner 1411. The transmit RF signal is routed by splitter/combiner 1411 onto the signal processing paths 1412a-1412d. The signal processing paths 1412a-1412d are configured to perform beam forming operations. The phase shifters 1413 perform phase shifting operations. In other examples, LO path phase shifting is implemented instead of signal path phase shifting. The BiVGAs 1414, 1415 amplify the phase shifted transmit RF signals and the switching circuits 1418 are operated during transmission to couple the amplified, phase shifted transmit RF signals to the input terminals of the PAs 1416, which provide the transmit RF signals with desired output power levels for over-the-air transmission. Switching circuits 1420 are operated during transmission to couple the amplified transmit RF signals output from the PAs 1416 to the antennas 1419.

In the receive direction, the switching circuits 1420 are operated during reception to couple the RF signal received by the antennas 1419 to the input terminals of the LNAs 1417, the outputs of which are coupled by switching circuits 1418 to the input terminals of the BiVGAs 1415. The process is then essentially the reverse of the process performed in the transmit direction. In the transmit and receive directions, the switched transformer arrays of the present disclosure are operated in the manner described above to transmit and receive, respectively, at the desired frequencies, e.g., to perform beamforming operations. For example, the switched transformer arrays may be incorporated into the PAs 1416 and/or the LNAs 1417 and the control bits can be selected to select the transmit and receive frequencies. In this way, each of the signal processing paths 1412 and/or the shared path in the rest of the wireless communications system 1400 can support multiple frequencies and/or a wide bandwidth. In contrast, in certain of the aforementioned split architectures, different frequencies or frequency bands (e.g., FR2a versus FR2b and/or FR2c) are processed by respective signal processing paths. In certain configurations, additional paths may also be used in the remaining portions of the wireless communications system in the aforementioned split architectures. Processing different frequencies with a common path(s), however, may enable size reduction and/or (fast) frequency hopping, for example due to a reduced time required to switch between relevant processing paths.

As indicated above, switched capacitor arrays (e.g., FIG. 8) can be used in combination with the switched transformer arrays (e.g., 610, 710) to fill in the frequency gaps between the center frequencies. In other words, the switched transformer arrays 610, 710 can be used to provide coarse tuning and the switched capacitor arrays can be used to provide fine tuning. In addition, spread spectrum frequency hopping can be performed with great agility by applying preselected sets of control bits to the switches on the transmitter and receiver ends of a communications link, which is useful for security applications as well as for broadband code division multiple access (CDMA) communications.

FIG. 15 shows a group of plots 1500 of the frequency responses of a PA that can have the configuration shown in FIG. 6 or 7, which incorporates one or more switched capacitor arrays (e.g., FIGS. 8, 820) and one or more switched transformer arrays (e.g., FIGS. 6, 610, FIGS. 7, 710). As indicated above, the switched transformer array is controlled or tuned to select the frequency band (i.e., coarse tuning, for example on the order of GHz) and the switched capacitor array is controlled or tuned to select the particular frequency within the band (for example, on the order of MHz). Changing the inductances of the transformers of the switched transformer array results in frequency tuning to the desired bands (e.g., LB/MB/HB, etc.) and the switched capacitor array further fine tunes the frequency within the selected band. The families of curves 1500 shown in FIG. 15 can be obtained by, for example, switching through an 8-bit switched capacitor array to reach the desired frequency around a particular band frequency. The plots 900 shown in FIG. 9 show an example of coarse tuning and the plots 1500 shown in FIG. 15 show an example of coarse+fine tuning. The range of frequency coverage largely depends on the min/max value of the capacitance in the switched capacitor array and the step size will depend on the resolution of the switched capacitor array (i.e., the number of control bits). Such a configuration can be used to cover, for example, the entire FR2 range (24 GHz to 71 GHz) in a BFIC that is approximately one-third the size of current BFICs that use the aforementioned split architecture to cover the FR2 range.

Implementation examples are described in the following numbered clauses:

1. A beamformer integrated circuit (BFIC) comprising a switched transformer array, the switched transformer array comprising:
a transformer primary side comprising at least a first transformer turn formed in a first metal layer of the BFIC and having first and second ends;
a transformer secondary side comprising at least a first transformer turn formed in a second metal layer of the BFIC and having first and second ends;
at least a first inductor strand formed in the first metal layer a first distance from the first transformer turn of the transformer primary side, the first inductor strand having first and second ends;
at least a second inductor strand formed in one of the first metal layer and the second metal layer a second distance from the first inductor strand, the second inductor strand having first and second ends;
a first switch configured to selectively interconnect the first and second ends of the first inductor strand; and
a second switch configured to selectively interconnect the first and second ends of the second inductor strand.

2. The BFIC of clause 1, wherein:
the first switch and the second switch are respectively configured to receive at least a first control bit and to be activated when said at least a first control bit is asserted and to be deactivated when said at least a first control bit is deasserted, wherein activation and deactivation of the first switch or the second switch changes electromagnetic inductive characteristics of the switched transformer array, thereby changing an operating frequency of the switched transformer array.

3. The BFIC of any of clauses 1-2, wherein the first distance is preselected to ensure electromagnetic inductive coupling between the first inductor strand and the first transformer turn of the transformer primary side when electrical current passes through the first inductor strand, wherein the second distance is preseletced to ensure electromagnetic inductive coupling between the second inductor strand and at least one of the first transformer turn of the transfomer primary side, the first transformer turn of the transfomer secondary side and the first inductor strand when electrical current passes through the second inductor strand.

4. The BFIC of any of clauses 1-3, wherein the transformer primary side further comprises at least a second transformer turn formed in a third metal layer of the BFIC, the second transformer turn of the transformer primary side having a first end that is connected by a via to the second end of the first transformer turn of the transformer primary side.

5. The BFIC of clause 4, wherein the transformer secondary side further comprises at least a second transformer turn formed in a fourth metal layer of the BFIC, the second transformer turn of the transformer secondary side having a first end that is connected by a via to the second end of the first transformer turn of the transformer secondary side.

6. The BFIC of any of clauses 1, 4 and 5, wherein the second metal layer is disposed in between the first and third metal layers and the third metal layer is disposed in between the second and fourth metal layers.

7. The BFIC of any of clauses 1-6, further comprising an amplifier circuit, the transformer primary side being connected to an electrical node of the amplifier circuit.

8. The BFIC of clause 7, wherein the electrical node is a drain of a cascode differential pair of the amplifier circuit.

9. The BFIC of clause 7, wherein the amplifier circuit is a multi-stage amplifier circuit comprising at least first and second amplifier stages, the transformer primary side being coupled to an output of the first amplifier stage and the transformer secondary side being coupled to an input of the second amplifier stage.

10. The BFIC of any of clauses 1-9, wherein the first and second inductor strands extend along opposite sides of the first transformer turn of the transformer primary side.

11. The BFIC of any of clauses 1-10, wherein the switched transformer array further comprises:
a third inductor strand formed in the first metal layer a third distance from the second inductor, the third inductor strand having first and second ends;
a fourth inductor strand formed in the first metal layer a fourth distance from the first inductor strand, the fourth inductor strand having first and second ends; and
third and fourth switches interconnecting the first and second ends of the third and fourth inductor strands, respectively, the third and fourth switches being configured to receive third and fourth control bits and to be activated when the third and fourth control bits are asserted, respectively, and to be deactivated when the third and fourth control bits are deasserted, wherein activation and deactivation of one or more of the first, second, third and fourth switches changes electromagnetic inductive characteristics of the switched transformer array, thereby changing an operating frequency of the switched transformer array.

12. The BFIC of clause 11, further comprising a switched capacitor array, and wherein values of the first, second, third and fourth control bits are selected such that activation of one or more of the switches achieves coarse frequency tuning of an operating frequency of a beamformer circuit of the BFIC to a desired frequency band, and wherein the switched capacitor array is configured such that control bits applied to the switched capacitor array cause the switched capacitor array to perform fine frequency tuning of the operating frequency of the beamformer circuit to a particular frequency within the desired frequency band.

13. A beamformer integrated circuit (BFIC) comprising a switched inductor array, the switched inductor array comprising:
N inductor strands formed in a first metal layer of the BFIC preselected distances from one another, where N is a positive integer that is greater than or equal to 3, each of the inductor strands having first and second ends and being substantially circularly shaped and concentrically oriented in the first metal layer; and
at least N−1 switches interconnecting the first and second ends of N−1 of the inductor strands, respectively, the N−1 switches being configured to be activated and to be deactivated, wherein activation of one or more of the switches changes electromagnetic inductive characteristics of the switched inductor array, thereby changing an operating frequency of the first inductor array.

14. The BFIC of clause 13, wherein an N^{th} inductor strand of the N inductor strands is disposed in a center of the N−1 inductor strands and operates as a primary transformer turn of the switched inductor array.

15. The BFIC of any of clauses 13-14, wherein the switched inductor array further comprises:
N inductor strands formed in a second metal layer of the BFIC preselected distances from one another, each of the inductor strands of the second metal layer having first and second ends and being substantially circularly shaped and concentrically oriented in the second metal layer; and
at least N−1 switches interconnecting the first and second ends of N−1 of the inductor strands of the second metal layer, respectively, the N−1 switches of the second metal layer being configured to be activated and deactivated, wherein activation of one or more of the switches of the interconnecting first and second ends of inductor strands of the second metal layer changes electromagnetic inductive characteristics of the switched inductor array, thereby changing an operating frequency of the first inductor array.

16. The BFIC of any of clauses 13-15, wherein an N^{th} inductor strand of the N inductor strands of the second metal layer is disposed in a center of the N−1 inductor strands of the second metal layer and operates as a secondary transformer turn of the switched inductor array.

17. The BFIC of any of clauses 13-16, further comprising an amplifier circuit, the transformer primary turn being being connected to a drain of a cascode differential pair of the amplifier circuit, wherein the amplifier circuit is a multi-stage amplifier circuit comprising at least first and second amplifier stages, the transformer primary turn being part of the first amplifier stage and the transformer secondary turn being part of the second amplifier stage.

18. The BFIC of clause 15, further comprising a switched capacitor array, and wherein values of control bits applied to the switched capacitor array are selected to cause activation of one or more of the switches in the switched inductor array to achieve coarse frequency tuning of an operating frequency of a beamformer circuit of the BFIC to a desired frequency band, and wherein the switched capacitor array is configured such that the control bits applied to the switched capacitor array cause the switched capacitor array to perform fine frequency tuning of the operating frequency of the beamformer circuit to a particular frequency within the desired frequency band.

19. A beamformer integrated circuit (BFIC) comprising:
a switched transformer array comprising:
a first transformer comprising a first transformer primary side and a first transformer secondary side, the first transformer primary side comprising at least a first transformer turn formed in a first metal layer of the BFIC and having first and second ends, the first transformer secondary side comprising at least a second transformer turn formed in a second metal layer of the BFIC and having first and second ends;
a second transformer comprising a second transformer primary side and a second transformer secondary side, the second transformer primary side comprising at least a third transformer turn formed in the first metal layer of the BFIC and having first and second ends, the second transformer secondary side comprising at least a fourth transformer turn formed in the second metal layer of the BFIC and having first and second ends;
a first inductor strand formed in the first metal layer a first distance from the first transformer turn, the first inductor strand having first and second ends;
a second inductor strand formed in the second metal layer a second distance from the second transformer turn, the second inductor strand having first and second ends;
a third inductor strand formed in the first metal layer a third distance from the third transformer turn, the third inductor strand having first and second ends; and a fourth inductor strand formed in the second metal layer a fourth distance from the fourth transformer turn, the fourth inductor strand having first and second ends.

20. The BFIC of clause 19, further comprising:
first, second, third and fourth switches interconnecting the first and second ends of the first, second, third and fourth inductor strands, respectively, the first, second, third and fourth switches being configured to be activated and deactivated, wherein activation and deactivation of one or more of the switches changes electromagnetic inductive characteristics of the switched transformer array, thereby changing an operating frequency of the switched transformer array.

21. A method for changing an operating frequency of beamformer circuitry of a beamformer integrated circuit (BFIC), the method comprising:
providing a switched transformer array and wherein the switched transformer array comprises a transformer primary side, a transformer secondary side, at least first and second inductor strands, and at least a first switch; and
asserting or deasserting at least a first control bit applied to at least the first switch of the swiched transformer array to cause the first switch to be activated or deactivated, respectively, the first switch interconnecting first and second ends of one of the first and second inductor strands, wherein activation and deactivation of the first switch changes electromagnetic inductive characteristics of the switched transformer array, thereby changing an operating frequency of the switched transformer array.

22. The method of clause 21, wherein the transformer primary side comprises at least a first transformer turn formed in a first metal layer of the BFIC and having first and second ends, the transformer secondary side comprising at least a first transformer turn formed in a second metal layer of the BFIC and having first and second ends, the first inductor strand being formed in the first metal layer a first preselected distance from the first transformer turn of the transformer primary side that is preselected to ensure electromagnetic inductive coupling between the first inductor strand and the first transformer turn of the transformer primary side when electrical current passes through the first inductor strand, the first inductor strand having first and second ends, the second inductor strand being formed in the first metal layer a second preselected distance from the first inductor strand that is preselected to ensure electromagnetic inductive coupling between the second inductor strand and at least one of the first transformer turn and the first inductor strand when electrical current passes through the second inductor strand.

23. The method of any of clauses 21-22, wherein the transformer primary side further comprises at least a second transformer turn formed in a third metal layer of the BFIC, the second transformer turn of the transformer primary side having a first end that is connected to the second end of the first transformer turn of the transformer primary side.

24. The method of any of clauses 21-23, wherein the transformer secondary side further comprises at least a second transformer turn formed in a fourth metal layer of the BFIC, the second transformer turn of the transformer secondary side having a first end that is connected to the second end of the first transformer turn of the transformer secondary side.

25. The method of clause 24, wherein the second metal layer is disposed in between the first and third metal layers and the third metal layer is disposed in between the second and fourth metal layers.

26. The method of any of clauses 21-25, further comprising an amplifier circuit, the transformer primary side being being connected to an electrical node of the amplifier circuit.

27. The method of clause 26, wherein the electrical node is a drain of a cascode differential pair of the amplifier circuit.

28. The method of any of clauses 26-27, wherein the amplifier circuit is a multi-stage amplifier circuit comprising at least first and second amplifier stages, the transformer primary side being part of the first amplifier stage and the transformer secondary side being part of the second amplifier stage.

29. A method for changing an operating frequency of beamformer circuitry of a beamformer integrated circuit (BFIC), the method comprising:
providing a switched inductor array comprising N inductor strands and at least a first switch interconnecting first and second ends of one of the N
inductor strands, the N inductor strands being formed in a first metal layer of the BFIC preselected distances from one another, the preselected distances being preselected to ensure electromagnetic inductive coupling between at least adjacent inductor strands when electrical current passes through the inductor strands, where N is a positive integer that is greater than or equal to 3; and
asserting or deasserting at least a first control bit applied to at least the first switch of the swiched inductor array to cause the first switch to be activated or deactivated, respectively, wherein activation and deactivation of the first switch changes electromagnetic inductive characteristics of the switched transformer array, thereby changing an operating frequency of the switched transformer array.

30. The method of clause 29, wherein the loops formed by the N inductor strands are arranged concetrically in the first metal layer, and wherein the loop of an N^{th} inductor strand of the N inductor strands is disposed in a center of the loops of the N−1 inductor strands and operates as a primary transformer turn of the switched inductor array.

31. The BFIC of clause 12, wherein the coarse frequency tuning is on the order of GHz, and the fine frequency tuning is on the order of MHz.

32. The BFIC of any of clauses 2-5, 11, 12, and 31, wherein the operating frequency is tunable over a range from approximately 24 GHz to approximately 71 GHz.

33. The BFIC of clause 18, wherein the coarse frequency tuning is on the order of GHz, and the fine frequency tuning is on the order of MHz.

34. The BFIC of any of clauses 13-18 and 33, wherein the operating frequency is tunable over a range from approximately 24 GHz to approximately 71 GHz.

Although selected aspects have been illustrated and described in detail, it will be understood that various substitutions and alterations may be made therein without departing from the spirit and scope of the present invention, as defined by the following claims.

What is claimed is:

1. A beamformer integrated circuit (BFIC) comprising a switched transformer array, the switched transformer array comprising:
a transformer primary side comprising at least a first transformer turn formed in a first metal layer of the BFIC and having first and second ends;
a transformer secondary side comprising at least a first transformer turn formed in a second metal layer of the BFIC and having first and second ends;
at least a first inductor strand formed in the first metal layer a first distance from the first transformer turn of the transformer primary side, the first inductor strand having first and second ends;
at least a second inductor strand formed in one of the first metal layer and the second metal layer a second distance from the first inductor strand, the second inductor strand having first and second ends;
a first switch configured to selectively interconnect the first and second ends of the first inductor strand; and
a second switch configured to selectively interconnect the first and second ends of the second inductor strand.

2. The BFIC of claim 1, wherein:
the first switch and the second switch are respectively configured to receive at least a first control bit and to be activated when said at least a first control bit is asserted and to be deactivated when said at least a first control bit is deasserted, wherein activation and deactivation of the first switch or the second switch changes electromagnetic inductive characteristics of the switched transformer array, thereby changing an operating frequency of the switched transformer array.

3. The BFIC of claim 2, wherein the first distance is preselected to ensure electromagnetic inductive coupling between the first inductor strand and the first transformer turn of the transformer primary side when electrical current passes through the first inductor strand, wherein the second distance is preseletced to ensure electromagnetic inductive coupling between the second inductor strand and at least one of the first transformer turn of the transfomer primary side, the first transformer turn of the transfomer secondary side and the first inductor strand when electrical current passes through the second inductor strand.

4. The BFIC of claim 2, wherein the transformer primary side further comprises at least a second transformer turn formed in a third metal layer of the BFIC, the second transformer turn of the transformer primary side having a first end that is connected by a via to the second end of the first transformer turn of the transformer primary side.

5. The BFIC of claim 4, wherein the transformer secondary side further comprises at least a second transformer turn formed in a fourth metal layer of the BFIC, the second transformer turn of the transformer secondary side having a first end that is connected by a via to the second end of the first transformer turn of the transformer secondary side.

6. The BFIC of claim 5, wherein the second metal layer is disposed in between the first and third metal layers and the third metal layer is disposed in between the second and fourth metal layers.

7. The BFIC of claim 5, further comprising an amplifier circuit, the transformer primary side being being connected to an electrical node of the amplifier circuit.

8. The BFIC of claim 7, wherein the electrical node is a drain of a cascode differential pair of the amplifier circuit.

9. The BFIC of claim 7, wherein the amplifier circuit is a multi-stage amplifier circuit comprising at least first and second amplifier stages, the transformer primary side being coupled to an output of the first amplifier stage and the transformer secondary side being coupled to an input of the second amplifier stage.

10. The BFIC of claim 6, wherein the first and second inductor strands extend along opposite sides of the first transformer turn of the transformer primary side.

11. The BFIC of claim 6, wherein the switched transformer array further comprises:
a third inductor strand formed in the first metal layer a third distance from the second inductor, the third inductor strand having first and second ends;
a fourth inductor strand formed in the first metal layer a fourth distance from the first inductor strand, the fourth inductor strand having first and second ends; and
third and fourth switches interconnecting the first and second ends of the third and fourth inductor strands, respectively, the third and fourth switches being configured to receive third and fourth control bits and to be activated when the third and fourth control bits are asserted, respectively, and to be deactivated when the third and fourth control bits are deasserted, wherein activation and deactivation of one or more of the first, second, third and fourth switches changes electromagnetc inductive characteristics of the switched transformer array, thereby changing an operating frequency of the switched transformer array.

12. The BFIC of claim 11, further comprising a switched capacitor array, and wherein values of the first, second, third and fourth control bits are selected such that activation of one or more of the switches achieves coarse frequency tuning of an operating frequency of a beamformer circuit of the BFIC to a desired frequency band, and wherein the switched capacitor array is configured such that control bits applied to the switched capacitor array cause the switched capacitor array to perform fine frequency tuning of the operating frequency of the beamformer circuit to a particular frequency within the desired frequency band.

13. A beamformer integrated circuit (BFIC) comprising a switched inductor array, the switched inductor array comprising:
N inductor strands formed in a first metal layer of the BFIC preselected distances from one another, where N is a positive integer that is greater than or equal to 3, each of the inductor strands having first and second ends and being substantially circularly shaped and concentrically oriented in the first metal layer; and
at least N−1 switches interconnecting the first and second ends of N−1 of the inductor strands, respectively, the N−1 switches being configured to be activated and to be deactivated, wherein activation of one or more of the switches changes electromagnetic inductive characteristics of the switched inductor array, thereby changing an operating frequency of the first inductor array.

14. The BFIC of claim 13, wherein an N^{th} inductor strand of the N inductor strands is disposed in a center of the N−1 inductor strands and operates as a primary transformer turn of the switched inductor array.

15. The BFIC of claim 14, wherein the switched inductor array further comprises:
N inductor strands formed in a second metal layer of the BFIC preselected distances from one another, each of the inductor strands of the second metal layer having first and second ends and being substantially circularly shaped and concentrically oriented in the second metal layer; and
at least N−1 switches interconnecting the first and second ends of N−1 of the inductor strands of the second metal layer, respectively, the N−1 switches of the second metal layer being configured to be activated and deactivated, wherein activation of one or more of the switches of the interconnecting first and second ends of inductor strands of the second metal layer changes electromagnetic inductive characteristics of the switched inductor array, thereby changing an operating frequency of the first inductor array.

16. The BFIC of claim 15, wherein an N^{th} inductor strand of the N inductor strands of the second metal layer is disposed in a center of the N−1 inductor strands of the second metal layer and operates as a secondary transformer turn of the switched inductor array.

17. The BFIC of claim 16, further comprising an amplifier circuit, the transformer primary turn being being connected to a drain of a cascode differential pair of the amplifier circuit, wherein the amplifier circuit is a multi-stage amplifier circuit comprising at least first and second amplifier stages, the transformer primary turn being part of the first amplifier stage and the transformer secondary turn being part of the second amplifier stage.

18. The BFIC of claim 15, further comprising a switched capacitor array, and wherein values of control bits applied to the switched capacitor array are selected to cause activation of one or more of the switches in the switched inductor array to achieve coarse frequency tuning of an operating frequency of a beamformer circuit of the BFIC to a desired frequency band, and wherein the switched capacitor array is configured such that the control bits applied to the switched capacitor array cause the switched capacitor array to perform fine frequency tuning of the operating frequency of the beamformer circuit to a particular frequency within the desired frequency band.

19. The BFIC of claim 18, wherein the coarse frequency tuning is on the order of GHz, and the fine frequency tuning is on the order of MHz.

20. The BFIC of claim 13, wherein the operating frequency is tunable over a range from approximately 24 GHz to approximately 71 GHz.
